(19) United States
(12) Patent Application Publication
(10) Pub. No.: US 2026/0371967 A1
(43) Pub. Date: Nov. 19, 2026

(54) SELF-ASSEMBLED PATTERNING METHODS

(71) Applicant: Tokyo Electron Limited, Tokyo (JP)

(72) Inventors: Ankur Agarwal, Austin, TX (US); Ryan Burns, Austin, TX (US); Michael Carcasi, Austin, TX (US)

(21) Appl. No.: 19/206,971

(22) Filed: May 13, 2025

(51) Int. Cl. H10P 50/00; G03F 7/00; G03F 7/20

(52) U.S. Cl. CPC H10P 50/695; G03F 7/0035; G03F 7/2028

(57) ABSTRACT

A method of patterning a substrate includes forming a plurality of base mandrels over the substrate from a base self-assembled pattern and performing a cyclic process to form a staircase pattern including steps. Each cycle of the cyclic process includes forming a new step of the staircase pattern using directed self-assembly. The base self-assembled pattern includes a base block-size ratio.

### TECHNICAL FIELD

The present invention relates generally to semiconductor processing, and in particular embodiments, to methods for patterning substrates.

### BACKGROUND

The fabrication of integrated circuits (ICs) generally requires the formation of numerous device elements on a semiconductor substrate. Traditionally, ICs are fabricated using photolithography. Lithographic methods form device elements by preparing a layer of photoresist on a substrate, partially exposing the photoresist to light through a patterned mask, developing the exposed photoresist to define a corresponding mask pattern in the photoresist layer, and then etching to transfer the pattern to the substrate.

At each successive semiconductor process node, the density of device elements increases, with corresponding decreases in parameters characterizing the size and placement of elements, such as the critical dimension (CD or feature width) and pitch (feature spacing). Indeed, CDs and pitches have decreased in size to a point that processes based on photolithography may rely on costly multiple-patterning techniques to produce devices within specifications. Future technology nodes may require additional multiple-patterning steps.

Similarly tight specifications exist in the field of optical waveguides and diffraction gratings. In augmented reality (AR) and virtual reality (VR) display systems, waveguides and diffraction gratings comprising high-refractive index materials may be used to direct light from a source to a user's eye while maintaining image quality and field of view. These components are generally patterned with features of CD and pitch comparable to or smaller than the wavelengths of visible light, between about 300 nm and about 1100 nm.

Directed self-assembly (DSA) has been identified as an alternative to multiple-exposure lithography for forming densely packed devices or tightly spaced gratings. DSA allows the patterning of fine features onto a substrate by using block copolymers or polymer blends that self-assemble onto the substrate in the presence of a relatively coarse guide pattern. Given such a pattern, the composition, molecular weight, and other properties of the polymers control the CD, pitch, and shape of the self-assembled features.

### SUMMARY

In an embodiment, a method of patterning a substrate includes forming a plurality of base mandrels over the substrate from a base self-assembled pattern and performing a cyclic process to form a staircase pattern including steps. Each cycle of the cyclic process includes forming a new step of the staircase pattern using directed self-assembly. The base self-assembled pattern includes a base block-size ratio.

In another embodiment, a method of patterning a substrate includes forming a self-assembled pattern over the substrate, the self-assembled pattern including a plurality of repeat units and an end block, each repeat unit including a plurality of blocks, each block in the plurality of blocks having a polymer composition shared with at most one other block in the plurality of blocks, the end block having a same polymer composition as one block in the plurality of blocks, the self-assembled pattern being symmetric with respect to a first mirror axis perpendicular to a direction of the repeat units; and performing a cyclic process to form a stepped pit, the stepped pit being symmetric with respect to a second mirror axis parallel to the first mirror axis. One cycle of the cyclic process includes selecting a target composition from the polymer compositions of the plurality of blocks; removing all blocks having the target composition from the plurality of blocks and the end block; and etching the substrate.

In still another embodiment, a method of patterning a substrate includes forming a first self-assembled pattern over a plurality of first neutral regions, the first self-assembled pattern including a first plurality of blocks having a first composition, a second plurality of blocks having a second composition, and a first block-size ratio between a first critical dimension of one of the first plurality of blocks and a second critical dimension of one of the second plurality of blocks; transferring the first self-assembled pattern to the plurality of first neutral regions to form a plurality of first neutral mandrels and a plurality of openings; coating the substrate with a neutral layer to cover the plurality of first neutral mandrels and fill the plurality of openings; forming a second self-assembled pattern over the neutral layer, the second self-assembled pattern including a third plurality of blocks having a third composition, a fourth plurality of blocks having a fourth composition, and a second block-size ratio between a third critical dimension of one of the third plurality of blocks and a fourth critical dimension of one of the fourth plurality of blocks, the second block-size ratio being different from the first block-size ratio; etching the third plurality of blocks to reveal portions of the neutral layer; etching the portions of the neutral layer to reveal the plurality of first neutral mandrels and form a staircase pattern; and etching the fourth plurality of blocks.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1H illustrate cross-sectional views of different stages of a method of patterning a substrate with a staircase pattern, wherein FIG. 1A depicts formation of a guide pattern comprising guides and neutral regions over the substrate, FIG. 1B depicts formation of a self-assembled pattern over a neutral region of the guide pattern, FIG. 1C depicts transfer of the self-assembled pattern to the neutral region to form a plurality of neutral mandrels, FIG. 1D depicts formation of a neutral layer over the plurality of neutral mandrels, FIG. 1E depicts formation of another self-assembled pattern comprising two pluralities of blocks over the neutral layer, FIG. 1F depicts etching of one of the pluralities of blocks to reveal portions of the neutral layer, FIG. 1G depicts etching of the portions of the neutral layer to reveal the plurality of neutral mandrels, and FIG. 1H depicts etching of the remaining plurality of blocks;

FIGS. 2A-2C illustrate symmetry properties of staircase patterns formed according to various embodiments, wherein FIG. 2A depicts translational symmetry of an embodiment pattern, FIG. 2B depicts a non-superimposable mirror reflection of the same embodiment pattern, and FIG. 2C depicts another possible staircase pattern that has a superimposable mirror reflection;

FIG. 3 illustrates assist layers that may be part of guides in a guide pattern, as well as possible polymer wetting properties of the guides and assist layers, according to various embodiments;

FIGS. 4A-4D illustrate cross-sectional views of different stages of a method of removing edge features from a substrate comprising a staircase pattern formed by (e.g.) the method of FIGS. 1A-1H, according to various embodiments, wherein FIG. 4A depicts a substrate with spacers deposited around the guides and a protective layer over the staircase pattern, FIG. 4B depicts etching of the spacers, FIG. 4C depicts removal of the edge features, and FIG. 4E depicts removal of the protective layer;

FIGS. 5A and 5B illustrate cross-sectional views of a method of removing guides and neutral mandrels from a substrate comprising a staircase pattern formed by (e.g.) the method of FIGS. 1A-1H, according to various embodiments, wherein FIG. 5A depicts removal of the guides and FIG. 5B depicts removal of the neutral mandrels;

FIGS. 6A-6E illustrate cross-sectional views of different stages of a method of patterning a substrate with a staircase pattern comprising steps by a cyclic process, according to various embodiments, wherein FIG. 6A depicts formation of a neutral layer over a staircase pattern comprising two steps, FIG. 6B depicts formation of a self-assembled pattern comprising a plurality of majority blocks and a plurality of minority blocks over the neutral layer, FIG. 6C depicts etching of the plurality of majority blocks to reveal portions of the neutral layer, FIG. 6D depicts etching of the neutral layer to form a new step of the staircase pattern, and FIG. 6E depicts etching of the plurality of minority blocks;

FIGS. 7A and 7B illustrate higher staircases that may be produced by a cyclic process of patterning a substrate, according to various embodiments, wherein FIG. 7A depicts a four-step staircase pattern and FIG. 7B depicts a five-step staircase pattern;

FIGS. 8A-8E illustrate a method of patterning a substrate by a cyclic process to form a stepped pit, wherein FIG. 8A depicts formation of a self-assembled pattern comprising triblock copolymers over a guide pattern, FIG. 8B depicts selection and removal of one of the polymer compositions of the triblock copolymers, FIG. 8C depicts etching of the substrate, FIG. 8D depicts formation of a two-step pit by selection and removal of another of the blocks of the triblock copolymers followed by etching, and FIG. 8E depicts formation of a three-step pit by selection and removal of the remaining block of the triblock copolymers followed by etching;

FIGS. 9A-9E illustrate formation of a staircase on a substrate patterned with a stepped pit, according to various embodiments, wherein FIG. 9A depicts filling of the stepped pit with a neutral layer followed by formation of a photoresist layer over the substrate, FIG. 9B depicts patterning of the photoresist layer aligned with a first step of the stepped pit, FIG. 9C depicts development of developable portions of the photoresist layer, FIG. 9D depicts etching of the neutral layer, and FIG. 9E depicts etching of the first step to form the staircase;

FIGS. 10A-10D illustrate cross-sectional views of different stages of a method of removing edge features from a substrate comprising a staircase pattern formed by (e.g.) the method of FIGS. 9A-9E, according to various embodiments, wherein FIG. 10A depicts patterning of a photoresist layer aligned with the edge features, FIG. 10B depicts development of developable portions of the photoresist layer, FIG. 10C depicts removal of the edge features, and FIG. 10D depicts stripping of the photoresist;

FIG. 11 illustrates structures comprising various constitutional units that may be part of polymer materials making up self-assembled patterns, guides, neutral layers, or block copolymers described herein, according to various embodiments;

FIGS. 12A and 12B together are a flow chart for a method of patterning a substrate, according to various embodiments, wherein FIG. 12A provides a first part of the method and FIG. 12B provides a second part of the method;

FIG. 13 is a flow chart for a method of patterning a substrate, according to various embodiments; and

FIG. 14 is a flow chart for a method of patterning a substrate, according to various embodiments.

### DETAILED DESCRIPTION OF ILLUSTRATIVE EMBODIMENTS

Directed self-assembly (DSA) methods are increasingly being used in semiconductor fabrication for applications like increasing the density of existing patterns (pitch splitting). DSA methods may, for example, be an attractive alternative to spacer methods in some process flows. But other challenges exist in semiconductor fabrication beyond reducing device footprints.

One such challenge is the formation of asymmetric features on substrates, such as extension of a contact or interconnect in a preferred direction in order to simplify later integration steps. Asymmetric patterns are also increasingly important for photonics and other optical applications. For example, augmented reality (AR) and virtual reality (VR) displays may comprise multiple waveguides and diffraction gratings, including input couplers that receive display information from light engines, expansion gratings that magnify the display, and output couplers that direct the light to a user's eyes. Such devices may incorporate waveguides or gratings with asymmetric features like staircases that rise (or fall) in a preferred direction without coming back down (or rising back up). Asymmetric gratings may also be incorporated into metasurfaces, which enable precise control of electromagnetic waves through subwavelength structuring.

Conventional multiple-exposure lithography can produce asymmetric patterns, but these processes may require precise alignment between exposures and entail significant costs in energy and material as the number of lithographic steps increases. Spacer methods and conventional DSA methods may be used in some applications to reduce the number of lithographic exposures required to fabricate a given pattern, but they typically produce patterns that are symmetric with respect to a mirror axis perpendicular to the direction of feature formation. Various embodiments described herein advantageously use DSA (and the rich chemistry of DSA polymers) to form staircase patterns that break this symmetry, or to form a stepped pit that can be etched subsequently to yield an asymmetric staircase, in processes that may be performed on-track. The embodiments disclosed herein may thus also provide a cost-effective alternative to conventional methods comprising lateral trim and vertical etch.

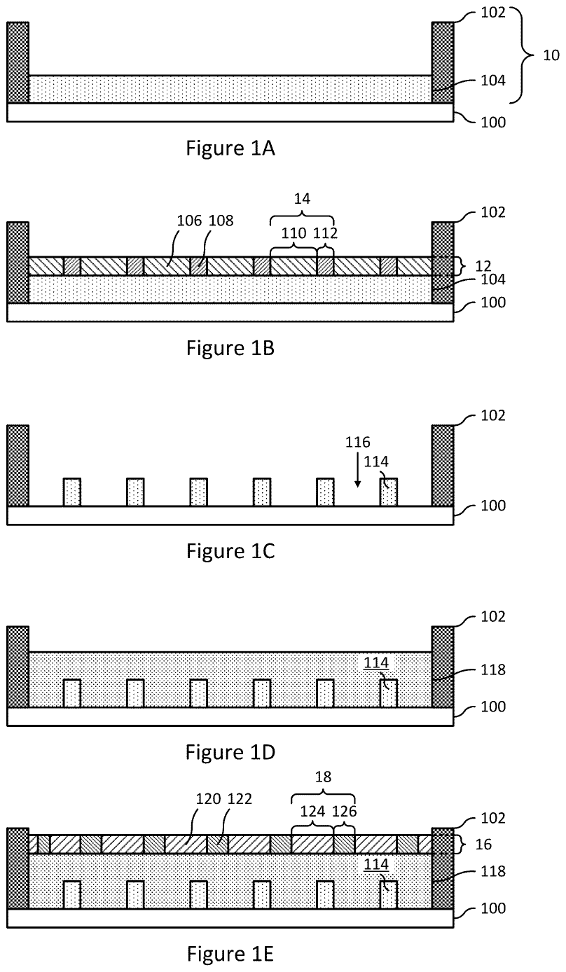

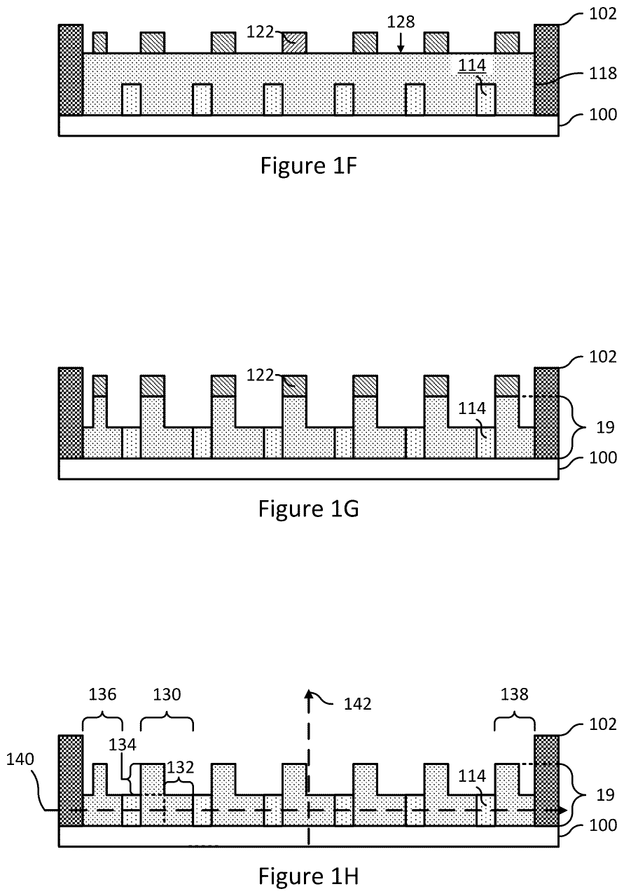

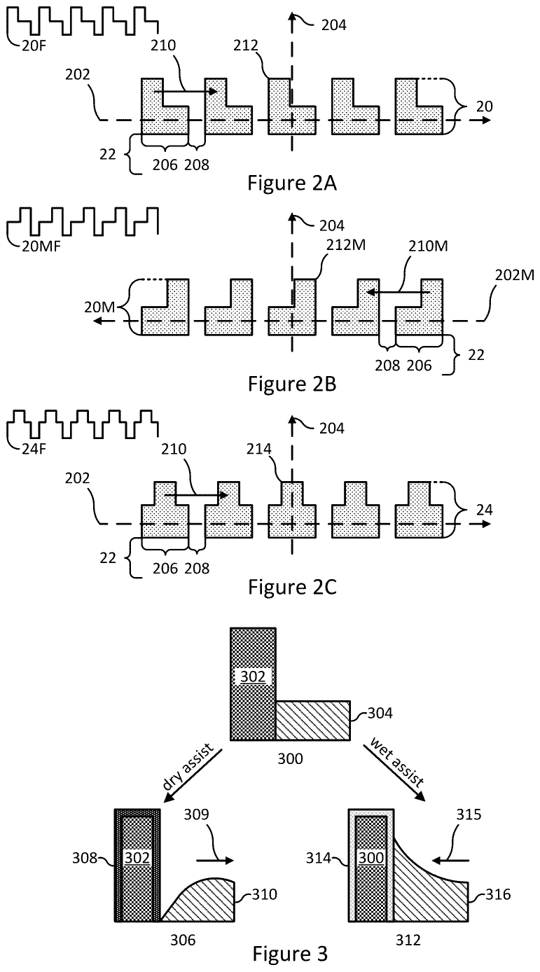

In the detailed description that follows, embodiments are described first with reference to a process flow for patterning a substrate with a staircase pattern comprising two steps, as illustrated in FIGS. 1A-1H. The illustrated embodiment and other staircase patterns fabricated according to embodiments discussed herein may be understood with respect to the symmetry properties of their cross sections with respect to a direction of the patterning. These symmetry properties are discussed with reference to FIGS. 2A-2C.

According to various embodiments, the process flow of FIGS. 1A-1H and later flows may comprise forming the staircase pattern using a self-assembled pattern that itself may be formed over a guide pattern. Guides of the guide pattern may themselves initially be prepared or later be modified to comprise an assist layer. Drying (repulsion) and wetting (attraction) of the self-assembled pattern by the assist layer is discussed for various embodiments with reference to FIG. 3.

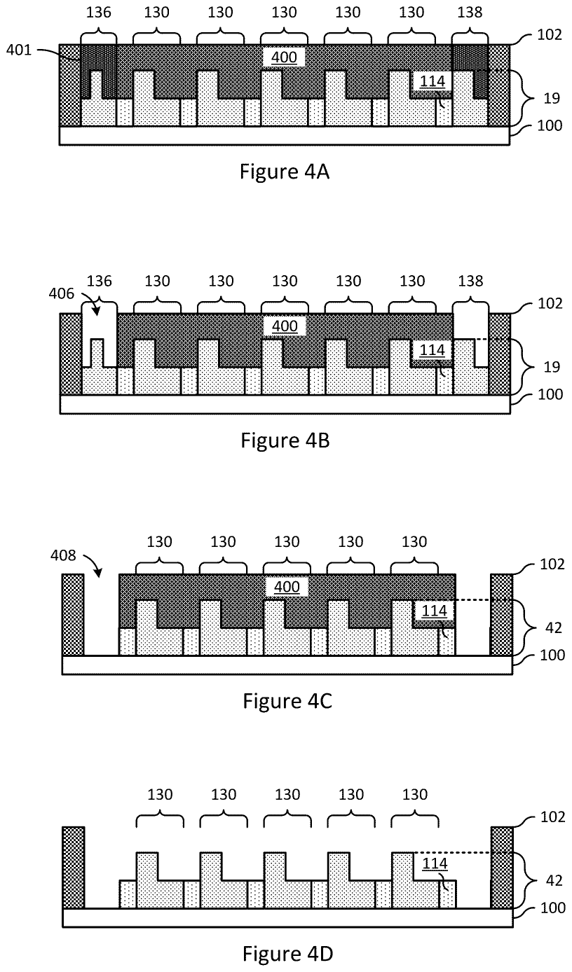

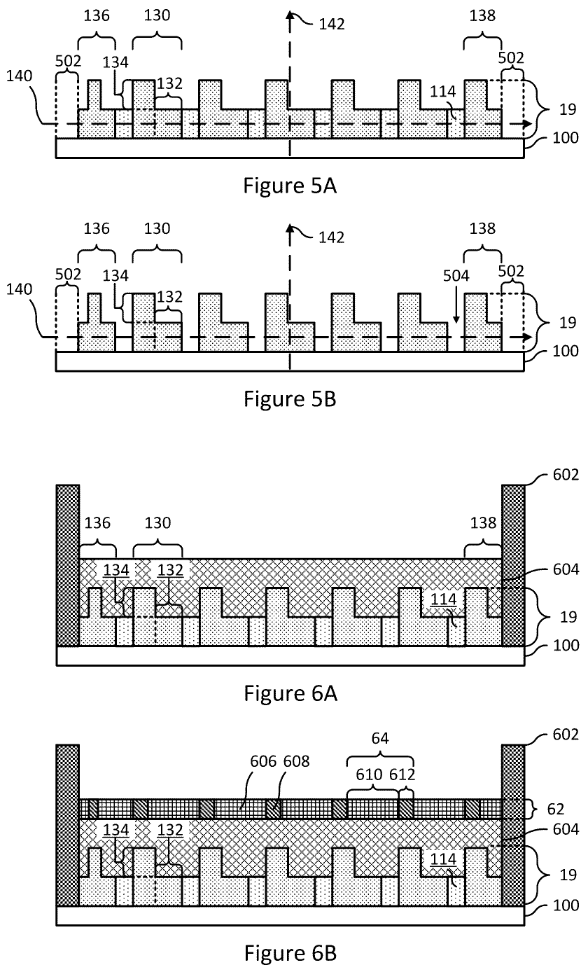

Further embodiments comprising removal of edge features formed near the guides and removal of the guides themselves are described with reference to FIGS. 4A-4D and FIGS. 5A and 5B, respectively.

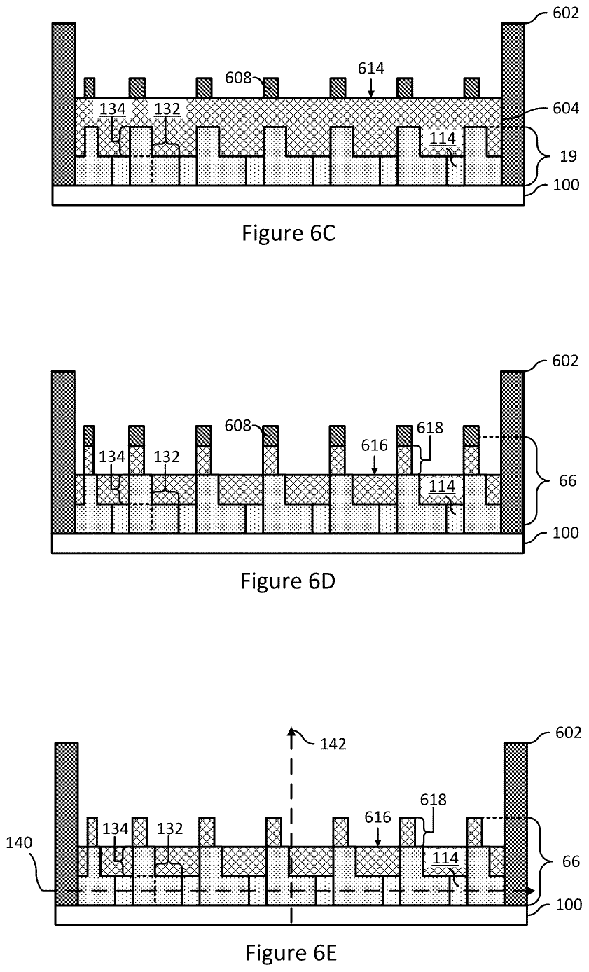

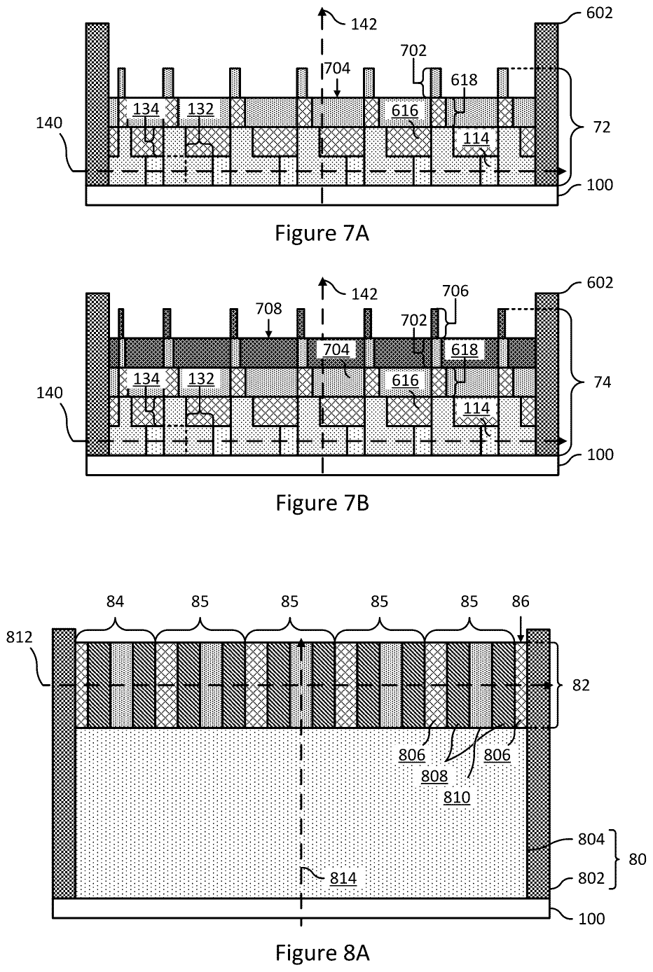

Various embodiments comprise formation of steps of a staircase pattern over a substrate by a cyclic process, each step being formed sequentially by directed self-assembly. The process flow of FIGS. 1A-1H may represent initial stages and a first cycle of these embodiments; a second cycle is described with reference to FIGS. 6A-6E. Staircase patterns resulting from additional cycles are described with reference to FIGS. 7A and 7B.

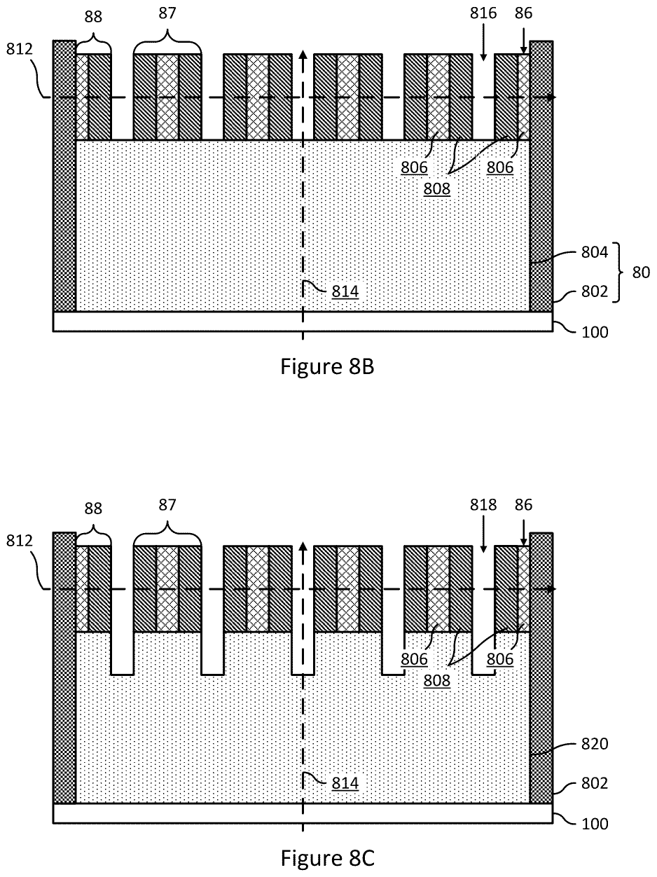

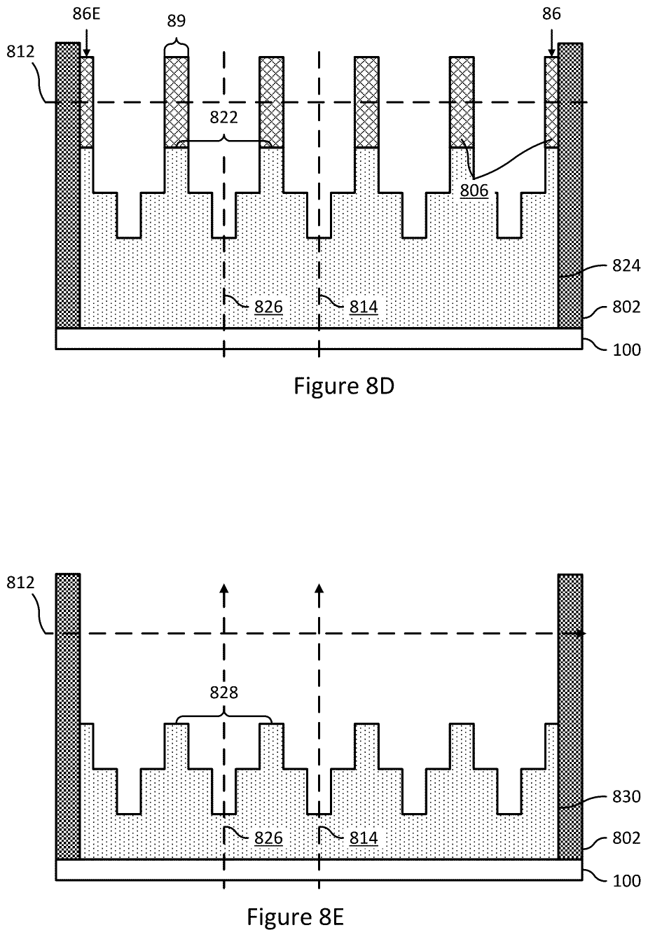

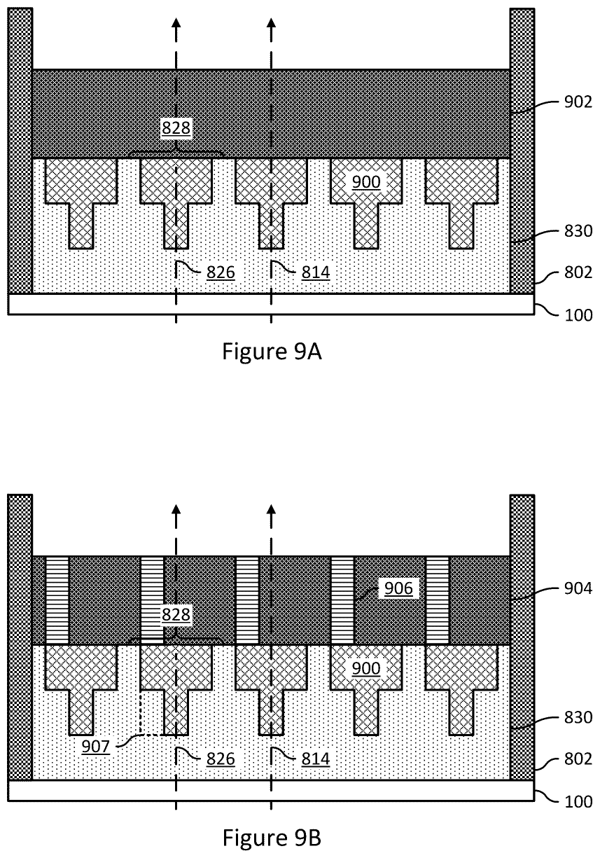

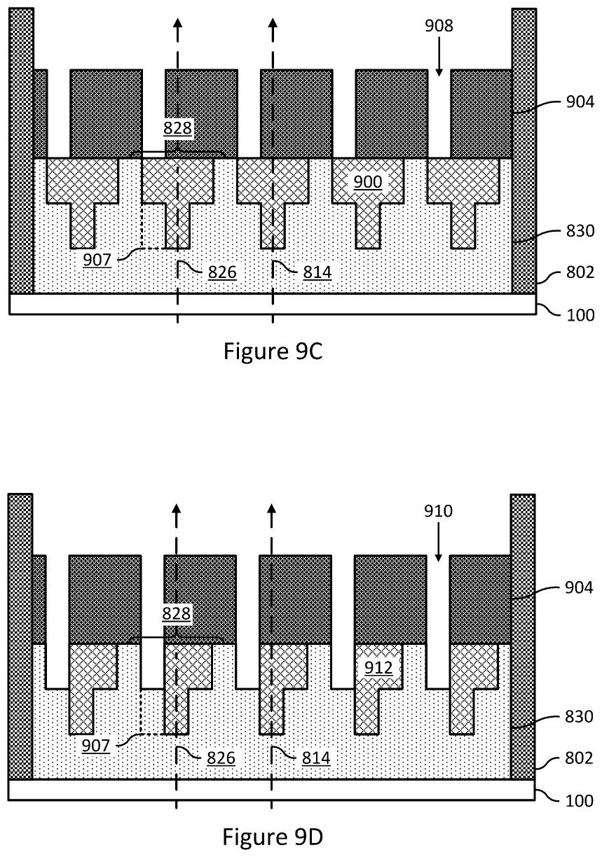

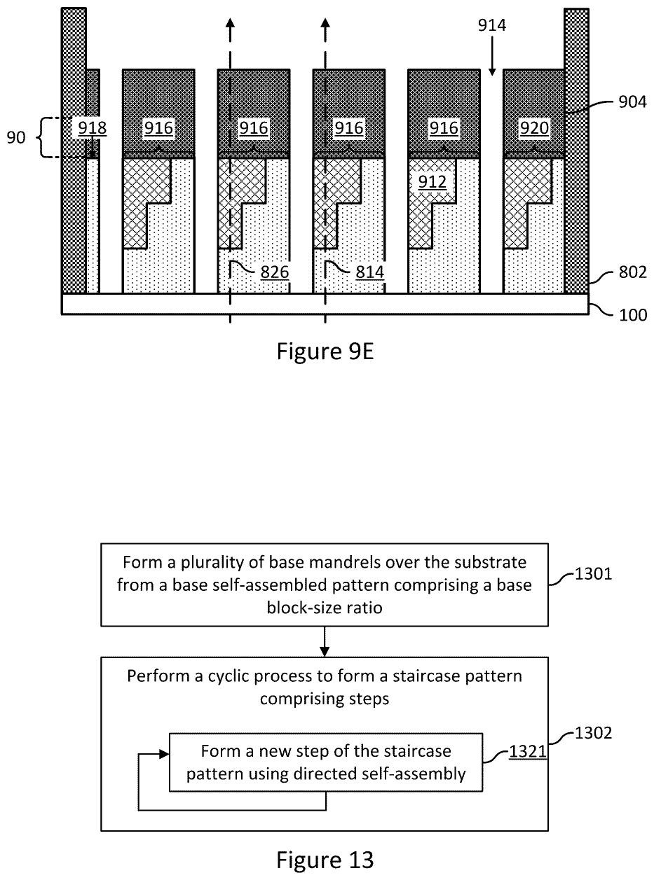

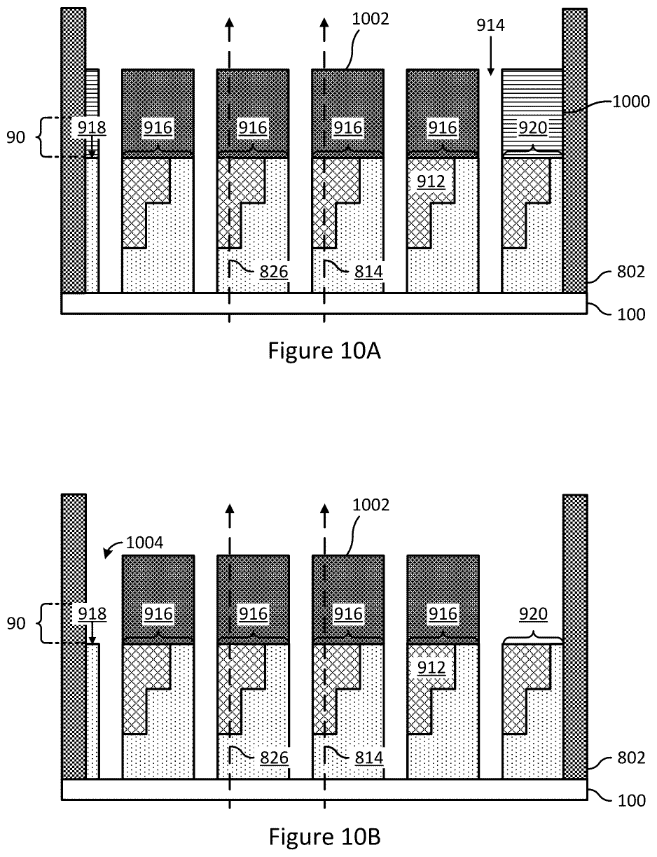

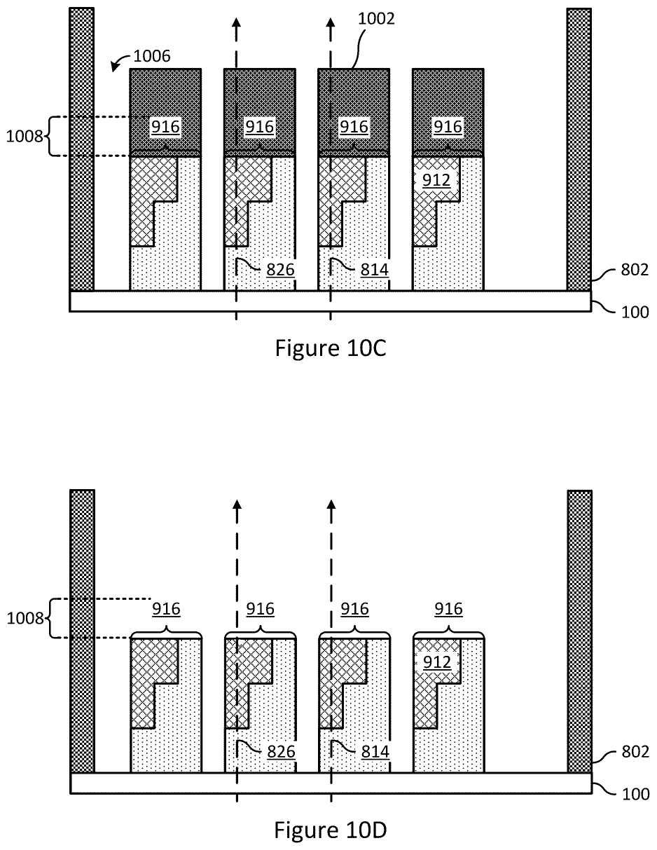

Various other embodiments comprise formation of a stepped pit over a substrate by a cyclic process, as described with reference to FIGS. 8A-8E. Formation of an opening through a step of the stepped pit to form a staircase is then described (according to embodiments) with reference to FIGS. 9A-9E. Embodiments further comprising removal of edge features are also described, with reference to FIGS. 10A-10D.

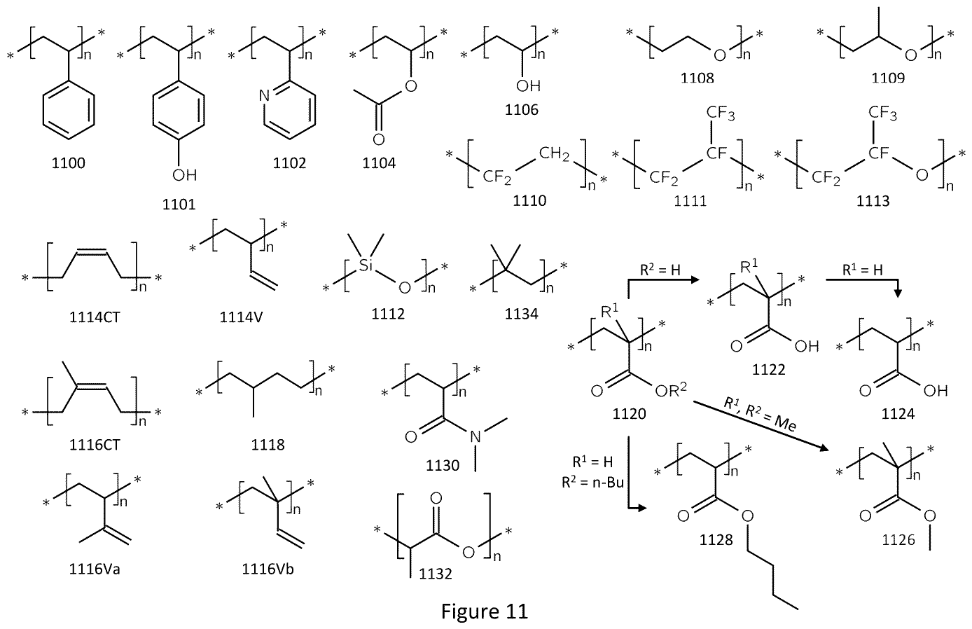

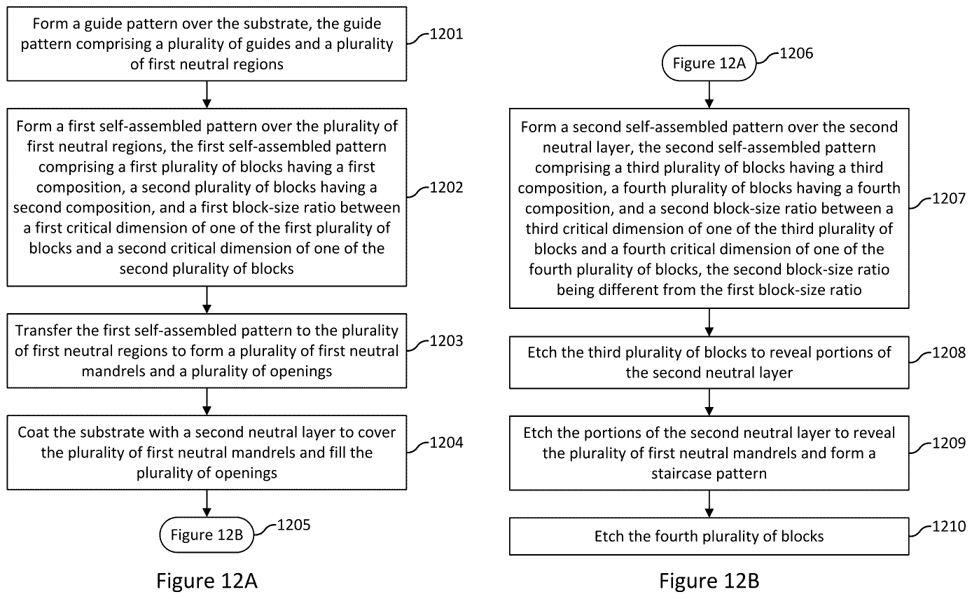

Examples of polymer materials suitable for use as part of embodiment self-assembled patterns and guide patterns are described throughout. These and other materials are discussed in greater detail with reference to FIG. 11. This detailed description then concludes by describing more general methods of patterning a substrate with reference to the flow charts presented in FIGS. 12-14.

FIGS. 1A-1H illustrate cross-sectional views of different stages of a method of patterning a substrate with a staircase pattern. Beginning with reference to FIG. 1A, a guide pattern 10 is formed over a substrate 100.

The substrate 100 represents generically any suitable substrate being processed in accordance with embodiments of the present disclosure. According to various embodiments, the substrate 100 may include bulk substrates such as silicon wafers, silicon-on-insulator (SOI) wafers, or any of various other semiconductor substrates. The substrate 100 may also be coated or layered with additional materials, including compound semiconductors, metal or metalloid oxides, or metal or metalloid nitrides. In some embodiments, the substrate 100 may include any material portion or structure of a device; in other embodiments, the substrate 100 may be patterned or embedded in a larger semiconductor structure or device, such as a reconstituted wafer in a wafer-level package process.

According to various embodiments, the substrate 100 may be or comprise a high-refractive index (RI) film. In some embodiments, the high-RI film may comprise a silicon-based material such as amorphous silicon, silicon dioxide (SiO₂) in forms such as quartz crystals or fused silica, other silicon oxide stoichiometries, silicon oxynitride (SiON compositions), or silicon nitride (Si₃N₄). In other embodiments, the high-RI film may comprise other inorganic oxides, such as titanium dioxide (titania, TiO₂), aluminum oxide (Al₂O₃), hafnium oxide (hafnia, HfO₂), zirconium dioxide (zirconia, ZrO₂), or tantalum pentoxide (Ta₂O₅). Still other embodiments of the high-RI film may comprise any of the aforementioned materials with an additional dopant, such as nitrogen-doped titania or aluminum-or yttrium-doped zirconia. In some embodiments, the high-RI film may comprise composites (such as metal oxide-nanoparticle composites) or ceramics (such as silicon aluminum oxynitride), including composites or ceramics of any of the aforementioned materials.

With further reference to FIG. 1A, the guide pattern 10 is a topographical guide pattern comprising a plurality of guides 102 and a plurality of neutral regions 104 disposed between pairs of guides. A sense in which a neutral material of the plurality of neutral regions 104 may be neutral is described further below with reference to interactions between the neutral material and blocks of a DSA formulation, according to various embodiments.

DSA methods using a topographical guide pattern (graphoepitaxy) consistent with the illustrated embodiments may comprise forming the plurality of guides 102 by lithographically patterning a photoresist material with trenches, partially filling the trenches with the neutral material by a suitable deposition or coating method (such as spin coating), and planarizing to remove any excess. According to embodiments, this process and other coating processes may be aligned to a global alignment such as a wafer notch of the substrate 100. In some embodiments, depositing or coating a neutral layer may be followed by a material hardening step, such as thermal baking, irradiation baking, vacuum baking, or the like.

The patterning may be performed using any suitable photolithography technology, such as dry lithography (e.g., 193 nm dry lithography), immersion lithography (e.g., 193 nm immersion lithography), deep UV (DUV) lithography (e.g., using 254 nm, 266 nm, or 284 nm UV radiation), i-line lithography (e.g., using 365 nm UV radiation), or h-line lithography (e.g., using 405 nm UV radiation). In some embodiments, the plurality of guides 102 may be formed by patterning a negative-tone or negative-tone developed (NTD) photoresist material with 193-nm (dry or immersion) lithography. According to various embodiments, a width of the guide pattern 10 may be between 100 nm and 500 nm. In some embodiments, a width of each guide in the plurality of guides 102 may be comparable to a target feature size, or smaller, in order to facilitate later removal and downstream fabrication. In certain embodiments, a width of each guide in the plurality of guides may be between 30 nm and 300 nm, for example, between 30 nm and 50 nm, or between 30 nm and 100 nm.

In other embodiments, though not as illustrated, the plurality of neutral regions 104 may be replaced by a single neutral underlayer that covers the substrate 100, with the plurality of guides 102 disposed over the neutral underlayer. In these latter embodiments, the plurality of guides 102 may be produced by forming a relatively coarse pattern of guide lines by conventional lithography. In still other embodiments, though again not as illustrated, the guide pattern 10 may be formed as a durable feature of a hard layer, such as a hard mask disposed over the substrate 100, or even the substrate 100 itself.

In FIG. 1B, a self-assembled pattern 12 is formed over the plurality of neutral regions 104. According to various embodiments, the self-assembled pattern 12 may be formed by directed self-assembly (DSA).

DSA formulations typically comprise (di-)block copolymers, macromolecules consisting of two chains of identical constitutional units that are covalently bonded, and denoted by AB or A-b-B (with A=. . . aaaa . . . , B=. . . bbbb . . . , and “-b-” indicating the covalent junction between blocks for clarity). In various embodiments, a DSA formulation may comprise a k-block copolymer with an integer number of blocks k≥3 having no fewer than 2 different compositions.

Embodiment DSA formulations may comprise a variety of polymer building blocks discussed below with reference to FIG. 11. In some embodiments, a DSA formulation may comprise polymer blends, ionic liquids, liquid crystals, or combinations and admixtures thereof and with block copolymers. In certain embodiments, a DSA formulation may further comprise additives that facilitate feature formation and hardening after coating and annealing, such as nanoparticles (with or without organic coatings), surfactants, or hardening agents.

According to embodiments, a DSA formulation may be dissolved or suspended in an organic solvent or solvent blend to facilitate dispensing and coating over a substrate. In various embodiments, the organic solvent may comprise an overcoat solvent such as methyl isobutyl carbinol, 1-butanol, isoamyl ether, or another such solvent that may be compatible with a photoresist material of the plurality of guides 102. In some embodiments, other solvents such as isopropanol, propylene glycol methyl ether acetate, or heptanones such as 2-heptanone may be used. In some embodiments, the organic solvent or solvent blend may also be chosen to facilitate phase separation between the blocks, such as by encouraging formation of polymer micelles (globular structures with a shell comprising one block surrounding a core of the other) due to preferential interactions with one of the blocks.

An embodiment DSA formulation may initially be coated over the guide pattern 10 in a film (not illustrated) comprising randomly oriented molecules using any suitable coating method, such as by a spin-on process (spin coating) dispensing the DSA formulation from a nozzle onto a spinning substrate. The film may be annealed (or activated) by thermal processing, such as by baking on a hot plate or in an oven above a formulation-dependent temperature T, typically chosen above the highest glass-transition temperature of the polymer blocks. For example, in diblock copolymer embodiments, T may be above the higher of T_{g}^{A} and T_{g}^{B} in order to ensure sufficient molecular mobility for self-assembly to occur. In some embodiments, the annealing temperature may be between 150 °C and 250 °C, and the annealing time may be between 5 min and 60 min.

In certain embodiments, the film may be exposed to solvent vapor before the thermal annealing in order to enhance mobility and facilitate self-assembly at temperatures closer to the block glass-transition temperatures. Solvent-vapor annealing may be performed for a period between 15 min and 3 h, according to various embodiments.

In some embodiments, the film may be annealed with light before the thermal annealing in order to promote uniform feature formation and alignment. In certain such embodiments, the light-based annealing method may be rapid thermal processing (RTP) of the entire film with light from a xenon flash lamp or halogen lamp. In other such embodiments, the light-based annealing method may be laser spike annealing (LSA) with a beam focused to a linear profile and scanned over the film. In certain embodiments, RTP or LSA may produce transient heating of the film to a peak temperature Tₚₑₐₖ exceeding an order-disorder transition temperature T_{odt} above which the DSA does not form ordered structures; as such, RTP or LSA may enable annihilation of high-energy defects. Peak temperature Tₚₑₐₖ may even exceed temperatures that would degrade or destroy the film if sustained during baking, and thus may enable significantly reduced thermal annealing times.

In some embodiments comprising LSA, the laser may have a wavelength of 532 nm and a power between 0.25 W and 1 W, and the beam may be focused to 100 μm×400 μm full width at half-maximum. The beam may be scanned over the film at a speed between 1 mm/s and 400 mm/s, resulting in an LSA dwell time (a ratio of beam width to scan speed) between 0.25 ms and 100 ms. A corresponding LSA processing time may be between 4 min and 15 min, in an embodiment. In other embodiments comprising LSA, the beam may be focused with different dimensions, different aspect ratio, or both (e.g., 90 μm×700 μm full width at half-maximum).

An assembled (post-annealing) configuration of the self-assembled pattern 12 may be determined, in various embodiments, by compositions of the DSA formulation and by their interactions with the plurality of guides 102 and the plurality of first neutral regions 104. In the first instance, the assembled configuration of a DSA formulation comprising a diblock copolymer depends on the volume fractions of blocks A and B (f_{A}, f_{B}∈[0,1] with f_{A}+f_{B}=1); a total number of constitutional units a and b in the copolymer, N=Nₐ+N_{b}, also called the degree of polymerization; and whether interactions between a and b units are more or less favorable, as quantified by a lower or higher Flory-Huggins parameter χ (a dimensionless quantity related to the enthalpy of mixing a and b units). The Flory-Huggins parameter χ of the blocks A and B should be positive, such that the polymers tend to phase separate rather than to mix.

Symmetric diblock copolymers (i.e., those with f_{A}=f_{B}) generally assemble into polymer lamellae (lines) when the product χN is above about 10.5. Below this value of χN, no ordered pattern forms; above this value, a wider range of volume fractions may form lines. The lines may comprise phase-separated regions in which like blocks (A or B) gather, with a boundary between the regions whose sharpness may correlate with measures of polymer flexibility such as a radius of gyration.

In the strong segregation limit (χN>>100), lines may form from diblock copolymers with f_{A} between about ⅓ and about ⅔. In this limit, increasing f_{A} further produces different assembled configurations, such as cylinders, spheres, or close-packed spheres of B in a matrix of A, before finally producing a random, dilute solution of B in A as f_{A} approaches 1. A gyroid phase comprising interpenetrating networks of A and B may separate lamellae from cylinders at intermediate values of χN. Accordingly, and in various embodiments, volume fractions of A and B may be between about ⅓ and about ⅔.

Interactions between a DSA film and an underlying layer during annealing may affect the self-assembly. (Indeed, this principle enables DSA methods using chemical rather than topographical guides, i.e., chemoepitaxy.) For example, if an underlying layer interacts favorably with block A and unfavorably with block B, annealing may produce a layer of B disposed over a layer of A and the underlying layer, rather than alternating lines. The plurality of neutral regions 104 may therefore, according to various embodiments, comprise a material that interacts approximately equally favorably with the blocks of the DSA formulation. In some embodiments, Flory-Huggins parameters between the blocks (A and B) and a neutral material (N) of the plurality of neutral regions 104 may have an absolute difference |χ_{AN}−χ_{BN}|≤0.05. In these and other embodiments, Flory-Huggins parameters between two or more types of DSA block and the neutral material may have an absolute difference of less than 0.025, less than 0.01, less than 0.005, or less than 0.001.

In some embodiments, the plurality of neutral regions 104 may comprise a random copolymer having the same constitutional units (e.g., a and b) as a block copolymer (e.g., AB) of the DSA formulation. Relative abundances of the constitutional units in the random copolymer may be selected to achieve equal affinity for A and B. In some of these embodiments, these abundances may differ from the volume fractions of the corresponding blocks.

In other embodiments, the plurality of neutral regions 104 may comprise a modified block copolymer of the DSA formulation, such as A′-b-B, A-b-B′, or A′-b-B′, where the primed letters indicate chemical modifications to the respective blocks that tune the interactions between them and between unmodified blocks of the DSA formulation to be more balanced. For example, replacing less than 1 mol % of styrene units in a block of polystyrene (PS) 1100 (see FIG. 11) with 4-hydroxystyrene units (cf. poly(4-hydroxystyrene) 1101) may yield sufficiently favorable interactions with a block of poly(methyl methacrylate) (PMMA) 1126 for the modified copolymer to function as a neutral layer for PS-b-PMMA.

In various embodiments, the plurality of neutral regions 104 may comprise polystyrene 1100, poly(4-hydroxystyrene) 1101, poly(methyl acrylate) (cf. a structure 1120 with pendant groups R¹=H and R²=Me=CH₃), poly(methyl methacrylate) 1126, or poly(4-hydroxystyrene)-b-poly(methyl methacrylate), with or without doping or chemical modifications such as oxidation. In some embodiments, the plurality of neutral regions 104 may comprise homopolymers or random copolymers with an organic backbone and sidechains comprising linear or branched alkyl groups (—CₘH₂ₘ₊₁), cycloalkyl groups (—CₘH₂ₘ₋₁), linear or branched fluoroalkyl groups (—CₘH₂ₘ₋ⱼ₊₁Fⱼ), fluorinated cycloalkyl groups (—CₘH₂ₘ₋ⱼ₋₁Fⱼ), linear or branched hydroxyalkyl groups (—CₘH₂ₘOH), or hydroxycycloalkyl groups (—CₘH₂ₘ₋₂OH) with positive integer m between 1 and 20. In embodiments comprising any of the fluorinated groups, non-negative integer j may be less than or equal to the corresponding number of hydrogens in the non-fluorinated equivalent, e.g., linear or branched fluorinated alkyl groups may have 0≤j≤2m+1.

In some embodiments, the plurality of neutral regions 104 may comprise a non-polymeric neutral material, such as spin-on carbon or spin-on glass, with or without doping or surface functionalization (such as oxidation or silylation) to tune interactions with blocks of the DSA formulation. Spin-on carbon may be an appropriate choice in embodiments comprising a relatively nonpolar DSA formulation, owing to its low surface energy. Conversely, spin-on glass has high surface energy and may be an appropriate choice in embodiments comprising a relatively polar DSA formulation.

With further reference to FIG. 1B, the (lamellar) self-assembled pattern 12 may comprise lines formed by a first plurality of blocks (A) 106 having a first critical dimension (CD₁) 110 and a second plurality of blocks (B) 108 having a second critical dimension (CD₂) 112. A corresponding block-size ratio may be given by a ratio BR=(CD₁/CD₂) in embodiments with CD₁≥CD₂ or by a ratio BR=(CD₂/CD₁) in embodiments with CD₂>CD₂.

A pitch 14 (or first pitch) of the self-assembled pattern 12 is a sum of the first critical dimension 110 and the second critical dimension 112. The pitch 14 may thus be a center-to-center distance between like features in the self-assembled pattern 12. According to embodiments, the self-assembled pattern 12 may have pitch 14 between 30 nm and 300 nm, for example, between 30 nm and 50 nm, between 30 nm and 100 nm, or between 50 nm and 200 nm.

For diblock copolymers, the pitch 14 may be predicted by Flory-Huggins theory to scale as lχ^{(1/6)}N^{(2/3)}=(l(χN)^{(2/3)}/\sqrt{χ}), where l is an effective length for the smallest independently mobile part of the polymer (“statistical segment length”). Using l~1 nm for flexible polymers and χN~10.5 gives a pitch of about (5 nm/\sqrt{χ}), with smaller pitches being achievable by increasing χ (choosing a different composition) or by decreasing N (using smaller polymers). For example, PS-b-PMMA has χ~0.0129, such that a corresponding pitch may be predicted to be about 42 nm when the degree of polymerization N is on the order of 800.

The pitch 14 may be tuned by a choice of a first composition of the first plurality of blocks 106 and a second composition of the second plurality of blocks 108, which together determine a corresponding Flory-Huggins parameter χ, as well as by a degree of polymerization N (correlating to a molecular weight) of the corresponding block copolymer. In various embodiments, DSA formulations may be prepared with fixed choices of the first and second compositions but varying copolymer molecular weight, such that chemical and physical properties of the respective pluralities of blocks 106 and 108 may remain broadly the same while the respective CDs 110 and 112 vary. In other embodiments, DSA formulations may comprise chemically distinct compositions that nevertheless produce patterns with comparable pitch.

In certain embodiments, CDs 110 and 112 may be tuned for a fixed pitch 14 by changing the volume fractions of the blocks. For example, a smaller volume fraction of block A (corresponding to the first plurality of blocks 106) may decrease CD₁ 110 and increase the CD₂ 112 (corresponding to the second plurality of blocks 108).

According to embodiments, the self-assembled pattern 12 may have a thickness (as indicated by the bracket) related to the pitch 14 by a multiplicative factor between 1 and 2. In some embodiments, the thickness of the self-assembled pattern 12 may be between 1.2 and 1.7 times the pitch 14. A thickness of about 1.5 times the pitch 14 may provide enough material for complete pattern formation and mechanical stability while avoiding the possibility that additional layers or structures may form.

With further reference to FIG. 1B, interactions between the a and b units and a guide material g of a guide feature G may determine whether the self-assembled pattern 12 is structured within the guide pattern 10 as GABA . . . ABAG or GBAB . . . BABG. The former case may correspond to embodiments in which the plurality of guides 102 interact more favorably with block A of the DSA than with block B (and vice versa for the latter case). As a result, the self-assembled pattern 12 may be self-aligning and symmetric around a midpoint of the guide pattern 10, with equal numbers, types, and arrangements of lines on either side. In the illustrated embodiment, the plurality of guides 102 interacts more favorably with the first composition of the first plurality of blocks 106. In other embodiments, the plurality of guides 102 may interact more favorably with the second composition of the second plurality of blocks 108. In various other embodiments described below, the plurality of guides 102 may comprise an assist layer configured to interact favorably (or unfavorably) with one of the blocks of the DSA formulation.

In various embodiments, a DSA formulation may produce a self-assembled pattern that is more or less commensurate with a width of the guide pattern 10. As illustrated in FIG. 1B, the self-assembled pattern 12 has a width that is approximately a whole-number multiple of the pitch 14 plus the first CD 110. As such, the self-assembled pattern 12 may fit comfortably within the guide pattern 10 and maintain favorable interactions between the first plurality of blocks 106 and the first plurality of guides 102. Even if the relationship between the width of the guide pattern 10, the pitch 14, and the first CD 110 is only approximate, the flexible nature of polymer materials may allow modest stretching or compression of the resulting pattern to accommodate a resulting strain, such that the pitch 14 and CDs 110 and 112 vary somewhat across the pattern. Variations from the ideal may generally be more pronounced near the plurality of guides 102 (i.e., at an edge of the self-assembled pattern 12) and less pronounced near a midpoint of the guide pattern 10.

If a width of the guide pattern 10 is too small or too large to accommodate a self-assembled pattern without excessive strain or misalignment of an unfavorably interacting block with the first plurality of guides 102, the self-assembled pattern may form defects, such as discontinuous lines, additional lines (similar to crystal dislocations), or bubbling of the self-assembled pattern such that it is no longer planar. In some embodiments, defects may be induced deliberately near the plurality of guides 102 in order to produce a desired arrangement or alignment of the DSA blocks nearer to the center of the guide region, or a desired arrangement or alignment of features formed subsequently that are aligned to the DSA blocks. For example, in some embodiments, defects may be induced deliberately in order to help align the plurality of neutral mandrels 114 (with reference to FIG. 1C below).

Deviations from an ideal pattern may be characterized, in some embodiments, by latitudes of the pluralities of blocks 106 and 108. A latitude may be determined for lines in a plurality of blocks according to the equation Lat=(wₘₐₓ−wₘᵢₙ)/(wₘₐₓ+wₘᵢₙ), where w denotes a line width and the “max” and “min” subscripts denote the largest and smallest widths of lines within that plurality. The latitude is an indicator function with range Lat∈[0,1], with Lat=0 corresponding to an ideal pattern. In some embodiments, the latitude may be used to identify edge features within a self-assembled pattern, for example, by examining variations in the latitude as lines within a given distance of the plurality of guides 102 are excluded from the calculation.

With reference now to FIG. 1C, the self-assembled pattern 12 may be transferred to the plurality of neutral regions 104 to form a plurality of neutral mandrels 114 and a plurality of openings 116. According to various embodiments, the pattern transfer may be performed by a sequence of selective etching steps (not illustrated).

A first selective etch may remove the first plurality of blocks 106 from the self-assembled pattern 12 while leaving the second plurality of blocks 108, the plurality of guides 102, and the plurality of neutral regions 104 intact. In various embodiments, the first selective etch may comprise a wet etch using a suitable solvent, a dry etch (such as a plasma etch or reactive ion etching) using an appropriate plasma chemistry, or a combination of each in succession. Some embodiments of the first selective etch may comprise a timed wet etch.

In embodiments of the first selective etch comprising a wet etch, a suitable solvent may be any solvent in which the first plurality of blocks 106 is soluble and other features are insoluble. In other such embodiments, suitable solvents for the first selective etch may be any solvent in which the first plurality of blocks 106 is soluble and the plurality of neutral regions 104 is only slightly soluble, such that undercutting of the second plurality of blocks 108 may be minimal or compensated by subsequent planarization, with the other features being insoluble.

According to various embodiments, a second selective etch may remove exposed portions of the plurality of neutral regions 104 while the second plurality of blocks 108 serves to mask unexposed portions. As such, in embodiments, the second selective etch may comprise a dry etch (such as a plasma etch or reactive ion etching) that does not entirely remove the second plurality of blocks 108 and leaves the plurality of guides 102 and the substrate 100 intact. The second selective etch may thereby form the plurality of neutral mandrels 114 and the plurality of openings 116.

After pattern transfer to the neutral layer, a third selective etch may remove any remaining portions of the second plurality of blocks 108 while leaving the plurality of neutral mandrels 114, the plurality of guides 102, and the substrate 100 intact. The third selective etch may comprise a wet etch using a suitable solvent or a dry etch (such as a plasma etch or reactive ion etching) using an appropriate plasma chemistry, according to various embodiments. In embodiments of the third selective etch comprising a wet etch, a suitable solvent may be any solvent in which the second plurality of blocks 108 is soluble and other features are insoluble, in some embodiments. In embodiments of the third selective etch comprising a wet etch, the wet etch may be a timed etch.

According to various embodiments, dry etches used to remove pluralities of blocks from a self-assembled pattern may comprise plasma etching with oxygen (O₂), ozone (O₃), carbon monoxide (CO), carbon dioxide (CO₂), hydrogen (H₂), admixtures and combinations thereof, or other suitable etch gases. In some embodiments, a dry etch may comprise successive etching with different etch chemistries, or cycles of successive etching. In certain embodiments comprising a self-assembled pattern comprising PS-b-PMMA, a dry etch suitable for removing PMMA blocks while leaving PS blocks intact may comprise cycles of successive etching with CO followed by a CO-H₂ mixture. PS blocks may then be removed by an oxygen-rich etch chemistry.

With reference now to FIG. 1D, a neutral layer 118 is coated over the substrate 100 to cover the plurality of neutral mandrels 114 and to fill the plurality of openings 116. The neutral layer 118 may be neutral (and comprise a neutral material) in the sense described above, and with respect to a second DSA formulation to be applied subsequently. The second DSA formulation may be different from the DSA formulation used to produce the self-assembled pattern 12, according to various embodiments. In some embodiments, the second DSA formulation may comprise the same constitutional units as the first DSA formulation but have differing volume fractions, degree of polymerization, or other characteristics. In some embodiments, and as described further below with reference to FIG. 3, the plurality of guides 102 may also be modified to comprise an assist layer that interacts differently with the second DSA formulation., such as by drying or wetting one of its blocks.

FIG. 1E depicts formation of a second self-assembled pattern 16 over the neutral layer 118. According to various embodiments, the second self-assembled pattern 16 may be formed from the second DSA formulation by DSA coating and annealing processes such as those described above. The second self-assembled pattern 16 may comprise a third plurality of blocks 120 and a fourth plurality of blocks 122 with corresponding third critical dimension (CD₃) 124 and fourth critical dimension (CD₄) 126 summing to give a second pitch 18. A corresponding second block-size ratio may be given by a ratio BR′=(CD₃/CD₄) in embodiments with CD₃≥CD₄ or by a ratio BR′=(CD₄/CD₃) in embodiments with CD₄>CD₃.

According to various embodiments, the second pitch 18 may be identical to the first pitch 14, such that self-alignment of the second self-assembled pattern 16 with the plurality of guides 102 may produce consistent positioning of the third and fourth pluralities of blocks 120 and 122 with respect to the plurality of neutral mandrels 114. In other embodiments, the second pitch 18 may approximate the first pitch 14 to within a tolerance, such that progressive accumulation of misalignment across the width of the guide pattern 10 may be controlled. For example, in some embodiments the second pitch 18 may be within 5% of the first pitch 14, or the second pitch 18 may be within 1% of the first pitch 14.

As illustrated in FIG. 1E, and in various embodiments, the second DSA formulation may be less commensurate with the width of the guide pattern 10 than the first DSA formulation was owing to changes in third and fourth CDs 124 and 126 and thus also in the second-block size ratio BR′. Strain in the self-assembled pattern 16 may thus give rise to defects near the plurality of guides 102 that help to align one of the pluralities of blocks 120 or 122 to edges of the plurality of neutral mandrels 114. In various embodiments, the aligned edges of the plurality of neutral mandrels 114 may be left edges or right edges.

In other embodiments (though not as illustrated), the plurality of neutral mandrels 114 may be formed and arranged such that the second self-assembled pattern 16 may be aligned to edges of the plurality of neutral mandrels 114 by selecting the second DSA formulation to be more nearly commensurate with the width of the guide pattern 10 than the first DSA formulation.

With reference now to FIG. 1F, the third plurality of blocks 120 may be removed by a fourth selective etch, along similar lines to those described above, that leaves the fourth plurality of blocks 122 and the plurality of guides 102 intact and reveals portions of the neutral layer 128. In embodiments of the fourth selective etch comprising a wet etch, a suitable solvent may be any solvent in which the third plurality of blocks 120 is soluble and other features are insoluble. In other such embodiments, suitable solvents for the fourth selective etch may be any in which the third plurality of blocks 120 is soluble and the neutral layer 128 is only slightly soluble, such that undercutting of the third plurality of blocks 120 may be minimal or compensated by subsequent planarization.

The portions of the neutral layer 128 may then be etched by a fifth selective etch, such as any dry etch that leaves the plurality of guides 102 intact, with the fourth plurality of blocks 122 serving as mask. The fifth selective etch may be performed until the plurality of neutral mandrels 114 is revealed, as illustrated in FIG. 1G. Accordingly, in some embodiments in which an etch chemistry of the fifth selective etch may also etch the plurality of neutral mandrels 114, the fifth selective etch may be a timed etch.

As illustrated in FIG. 1G, the fifth selective etch forms a staircase pattern 19 from the neutral layer 118. Removal of any remaining portions of the fourth plurality of blocks 122 by a sixth selective etch, which may be a wet or dry etch that leaves the plurality of guides 102, the staircase pattern 19, and any remaining portions of the plurality of neutral mandrels 114 intact, according to various embodiments. The sixth selective etch thus reveals the staircase pattern 19, as illustrated in FIG. 1H.

The staircase pattern 19 comprises one or more copies of a staircase 130 (5 copies, as illustrated in FIG. 1H) separated by the plurality of neutral mandrels 114. The staircase 130 comprises a first step 132 and a second step 134. In some embodiments, a width of the staircase 130 may be equal to the first pitch 14 or the second pitch 18. In various embodiments, the staircase may have a width between 30 nm and 300 nm, for example, between 30 nm and 50 nm, or between 30 nm and 100 nm.

The staircase pattern 19 may also comprise edge features, such as a left edge feature 136 and a right edge feature 138 depicted in FIG. 1H. Edge features may arise from misalignments or defects of the second self-assembled pattern 16 in near the plurality of guides 102, as described above. (Embodiments comprising edge removal will be discussed below with reference to FIGS. 4A-4D.) Symmetry properties of the staircase pattern 19 may now be analyzed by considering mirror reflections with respect to a mirror axis 142 perpendicular to a (lateral) direction 140 of the first neutral mandrels 114.

FIGS. 2A-2C illustrate symmetry properties of staircase patterns formed according to various embodiments. FIG. 2A depicts an ideal staircase pattern 20 obtained by taking the staircase pattern 19 of FIG. 1H and omitting the edge features 136 and 138. A direction 202 of the staircase pattern is collinear with the direction of the neutral mandrels 140.

If the ideal staircase pattern 20 were extended indefinitely along the direction 202, it would have translational symmetry, i.e., moving the pattern to the left or to the right (as illustrated by translation 210) by a pattern spacing 22 would produce an identical pattern. The pattern spacing 22 is a sum of a staircase width 206 and a staircase spacing 208 that matches a critical dimension of the neutral mandrels 114. No translational symmetry exists for the ideal staircase pattern 20 along a perpendicular direction (mirror axis) 204. Thus, the ideal staircase pattern 20 corresponds to a staircase frieze 20F.

Friezes associated with the direction 202 and the mirror axis 204 may exhibit a limited number of symmetries beyond translational symmetry along the direction 202. Those symmetries are horizontal reflections through a mirror axis collinear with direction 202; vertical reflections through the mirror axis 204; glide reflections that are equivalent to performing a translation 210 and a vertical reflection (in either order); and 180° rotations around an intersection of the direction 202 and the mirror axis 204.

A staircase pattern 19 formed consistent with embodiments may comprise steps of monotonically decreasing width, aligned to one side of the pattern and rising away from a substrate (such as substrate 100). According to various embodiments, the steps may be aligned on the left side or the right side. In some embodiments, the steps may not be aligned uniformly, but each step may lie entirely over the next lower step. In some such embodiments, one or more adjacent steps may still be aligned to each other.

The design constraints just described preclude the corresponding ideal staircase pattern 20 from exhibiting horizontal mirror symmetry, glide symmetry, and rotational symmetry. Relaxing these constraints may enable formation of staircase structures with other features, such as inverted or partially buried staircases; overhanging of one or more lower steps by a higher step; nonmonotonic staircases; and the like, some of which may be characterized by additional symmetries.

Vertical mirror symmetry is of particular interest here. The plurality of neutral mandrels 114, which may be formed in various embodiments by a single conventional DSA process as described above, exhibits vertical symmetry with respect to reflections through the mirror axis 142 (collinear with mirror axis 204). But advantageously, and according to embodiments, the staircase pattern 19 formed by sequential DSA processes comprising identical or similar pitch but different block-size ratios may deliberately break this symmetry.

As illustrated in FIG. 2B, reflecting the corresponding ideal staircase pattern 20 and staircase frieze 20F across the mirror axis 204 produces a mirrored staircase pattern 20M and mirrored staircase frieze 20MF. The pattern spacing 22 is a scalar and not affected by the reflection, so the mirrored translation 210M remains a symmetry. Nevertheless, the mirrored staircase pattern 20M cannot be superimposed on the original pattern. If FIGS. 2A and 2B were superimposed, a second step of a central staircase 212 would be on an opposite side of mirror axis 204 from a second step of a mirrored central staircase 212M. The ideal staircase pattern 20 is thus a chiral frieze belonging to frieze group p1 (translational symmetry only).

In some embodiments, as illustrated in FIG. 2C, a symmetrical staircase pattern (stepped pyramid) 24 may be formed, with each higher step centered over the next lower step. (A corresponding symmetrical staircase frieze 24F is also depicted.) A central stepped pyramid 214 of such a pattern possesses vertical mirror symmetry, such that the symmetrical staircase pattern is an achiral frieze belonging to frieze group p1m1 (adding vertical reflection symmetry to the translational symmetry of p1).

As mentioned above, and according to embodiments, interactions between blocks of a DSA formulation and guides of a guide pattern (such as the plurality of guides 102 in the guide pattern 10) may enable the DSA to self-align while forming a self-assembled pattern (such as self-assembled pattern 12 or second self-assembled pattern 16). FIG. 3 illustrates assist layers that may be part of guides in a guide pattern, as well as possible polymer wetting properties of the guides and assist layers, according to various embodiments.

With reference to FIG. 3, a neutral interaction 300 between a guide 302 and a polymer composition of a polymer film 304 may be characterized by the polymer film 304 having a flat surface near the guide 302. According to various embodiments, the guide 302 may be modified through various means before the polymer film 304 is introduced, such that the guide 302 comprises an assist layer along its perimeter. In various embodiments, the assist layer may interact unfavorably or favorably with the polymer composition of the polymer film 304.

An unfavorable interaction 306 between a dry-assist layer 308 of the guide 302 and the polymer composition of the polymer film 310 may be characterized by the polymer film 310 having a convex surface near the guide 302. This convexity may arise because an assist layer-polymer interface has high surface energy, for example, the dry-assist layer 308 may comprise polar functional groups like hydroxyls (—OH) while the polymer composition comprises nonpolar functional groups like alkyls (or vice versa). Irrespective of any microscopic explanation or theory, this convexity may be associated with the polymer film 310 receding or drying 309 from the guide, according to embodiments. Drying 309 may thin the polymer film 310 near the guide 302, and because corresponding volume near the guide may be excluded from filling by the polymer composition, the size of a corresponding block in a self-assembled pattern may grow.

A favorable interaction 312 between a wet-assist layer 314 of the guide 302 and the polymer composition of the polymer film 316 may be characterized by the polymer film 316 having a concave surface near the guide 302. This concavity may arise because an assist layer-polymer interface has low surface energy, for example, the wet-assist layer 314 and the polymer composition may comprise similar functionalities. Irrespective of any microscopic explanation or theory, this concavity may be associated with the polymer film 316 advancing along or wetting 315 the guide, according to embodiments. Wetting 315 may affect the homogeneity of the polymer film 316 near the guide 302, and because some portion of the polymer fills volume above a corresponding surface of the (flat) polymer film 304, the size of a corresponding edge block in a self-assembled pattern may shrink.

In other words, and according to embodiments, forming or modifying the plurality of guides 102 of the guide pattern 10 such that the guides comprise an assist layer may provide additional control over the details of self-assembled patterns formed by each DSA step, both globally (by helping to determine pattern alignment and propensity for defect formation) and locally (by tending to grow or shrink blocks at the edges of a self-assembled pattern that give rise to edge features).

According to embodiments, an assist layer may be formed through various surface modification techniques, such as wet etching of a guide surface; ion implantation; chemical substitution to introduce surface-active functional groups like halogen atoms, organic functionalities like alkyl groups or aryl groups (derivatives of phenyl, —C₆H₅), or other moieties like siloxyls (—OSiR₃, where each R group may for example be a separately selected alkyl) or thiols (—SH); and the like.

In various embodiments, ion implantation may comprise bombarding the guide surface with energetic ions such as oxygen ions to form surface oxides or hydroxyls, nitrogen ions to form surface nitrides or amines (—NH₂), or fluorine ions to form fluorinated surfaces. The penetration depth and concentration of implanted species may be controlled through ion energy and dose, respectively.

In some embodiments, an assist layer may be deposited over the guide subsequent to ion implantation, using methods such as area-selective deposition methods. In some embodiments comprising distinct modifications of each guide in a region (such as the region depicted in FIGS. 1A-1H), successive ion implantation steps may be used to perform area-selective deposition of distinct assist layers.

According to various embodiments, one or both guides of a guide pair may comprise or be modified to comprise an assist layer. The modification may be performed before formation of any self-assembled pattern, between formation of successive self-assembled patterns, or both. For example, in embodiments such as that illustrated in FIGS. 1A-1H, the guides 102 may initially comprise an assist layer configured to be wetted by the first composition or the second composition. Before forming the second self-assembled pattern over the neutral layer 118, the assist layer may be modified to be wetted by the third composition or the fourth composition.

The ability to control wetting behavior through assist layers may increase pattern density in some embodiments, where pattern density refers to the number of target features (such as staircases) within a given guide region. For example, in embodiments comprising an assist layer, a pattern density of a staircase pattern may be increased by 1, by 2, or by a higher integer. While complete elimination of edge features may not be achievable, in some embodiments higher wetting may reduce edge-feature width sufficiently that subsequent edge-removal processes may require less time, energy, and reagents. In other embodiments, lower wetting may increase edge-feature width where desirable, e.g., for inducing specific defects. According to various embodiments, control over edge-feature dimensions through wetting or drying behavior may provide advantageous flexibility in achieving target pattern designs.

FIGS. 4A-4D illustrate cross-sectional views of different stages of a method of removing edge features from a substrate comprising a staircase pattern 19, according to various embodiments.

To begin edge removal, according to some embodiments, a spacer material layer (not illustrated) may be deposited conformally over the substrate 100 using a deposition method such as atomic layer deposition, chemical vapor deposition, or the like. The spacer material may comprise silicon oxide, silicon nitride, or other dielectric materials compatible with subsequent etching steps, according to embodiments.

The spacer material layer may be etched such that a resulting plurality of spacers 401 may be aligned with edge features 136 and 138. In embodiments (not illustrated) in which the edge features are different sizes, the etching may be performed such that the spacers are aligned separately. A protective layer 400 may then be coated over the staircase pattern 19 to protect the staircases 130 during subsequent processing, as depicted in FIG. 4A. According to various embodiments, the protective layer 400 may comprise spin-on carbon, spin-on glass, or a hard mask.

In FIG. 4B, the plurality of spacers 401 is etched to form edge openings 406 and to expose the edge features 136 and 138. In various embodiments, this etch process may be a dry etch such as a plasma etch or reactive ion etching, as described above. Then, as depicted in FIG. 4C, the edge features 136 and 138 may be removed through the edge openings 406, forming cleaned edges 408. According to various embodiments, when the spacer material and the material of the edge features 136 and 138 have comparable etch selectivity, spacer etching and edge removal may be performed as a continuous process. In other embodiments, the edge features 136 and 138 may be removed using a second etch chemistry selective for the edge feature material.

After etching, the staircases 130 together form a trimmed staircase pattern 42. In FIG. 4D, the protective layer 400 is removed to reveal the trimmed staircase pattern 42.

FIGS. 5A and 5B illustrate cross-sectional views of a method of removing guides and neutral mandrels from a substrate comprising a staircase pattern formed by (e.g.) the method of FIGS. 1A-1H, according to various embodiments.

Referring to FIG. 5A, and in various embodiments, the plurality of guides 102 may be removed by a dry etch process, like those described above, that leaves the staircase pattern 19 and the substrate 100 intact. In some embodiments, though not as illustrated, the dry-etch process may remove a portion of the neutral mandrels 114. Guide gaps 502 left behind after etching may have widths corresponding to the widths of the removed plurality of guides 102.

In FIG. 5B, any remaining portion of the plurality of first neutral mandrels 114 is etched to form a plurality of staircase spacings 504 separating staircases 130 of the staircase pattern 19. According to various embodiments, the plurality of neutral mandrels 114 may be removed by a dry or wet etch process that leaves the staircase pattern 19 and the substrate 100 intact, such as those described above. The width of each staircase spacing 504 may correspond to a width of the corresponding removed neutral mandrel 114.

In the embodiments illustrated, guide removal is performed without having first performed a spacer-based edge removal process like the one described above with reference to FIGS. 4A-4D. In embodiment processes in which it is desirable to remove edge features 136 and 138 after removal of the guides, an alternate edge-removal process may be used. For example, in these embodiments edge removal may comprise coating a photoresist material over the substrate; patterning the photoresist with developable regions aligned to the edge features and undevelopable regions; developing the developable regions of the photoresist; etching the edge features; and stripping the undevelopable regions of the photoresist.

FIGS. 6A-6E illustrate cross-sectional views of different stages of a method of patterning a substrate with a staircase pattern comprising steps by a cyclic process, according to various embodiments. Because the workpiece depicted in FIG. 6A is structurally similar to the outgoing substrate depicted in FIG. 1H, like reference numerals are used to refer to like structures.

In various embodiments, an incoming substrate may comprise a graphoepitaxy guide pattern (i.e., a plurality of guides 602 and a plurality of neutral regions) disposed over a substrate 100, which may be a substrate in the sense described above. A plurality of neutral mandrels (or plurality of base mandrels) 114 may be formed over the substrate 100 from a base self-assembled pattern comprising a base block-size ratio. In various embodiments, the base self-assembled pattern may be a DSA pattern formed as described with reference to FIGS. 1A-1C.

The plurality of base mandrels 114 having been prepared, a cyclic process may be performed to form a staircase pattern comprising steps. Each cycle of the cyclic process may comprise forming a new step of the staircase pattern using directed self-assembly, i.e., by repeated DSA processes like those described above with reference to FIGS. 1D-1H. A first cycle of the cyclic process may form a first step 132 and a second step 134 of the staircase pattern, according to embodiments, thereby producing a staircase pattern 19. Subsequent cycles of the cyclic process may form a single new step.

Referring now to FIG. 6A, a second neutral layer 604 is coated over the substrate 100 to cover the staircase pattern 19. The second neutral layer 604 may be neutral (and comprise a second neutral material) in the sense described above, and with respect to a third DSA formulation to be applied subsequently. According to various embodiments, an etch-stop liner (not illustrated) may be deposited over the staircase pattern 19 before coating the second neutral layer 604 to enable selective removal of neutral materials in later processing steps. The etch-stop liner may comprise materials such as silicon nitride, titanium nitride, aluminum nitride, silicon oxide, aluminum oxide, other metal oxides, silicon carbide with n-type doping (e.g., N or P) or p-type doping (e.g., B, Al, Ga), or other materials having good etch selectivity with respect to both the second neutral layer 604 and the underlying staircase pattern 19.

In FIG. 6B, a third self-assembled pattern 62 is formed over the second neutral layer 604. According to various embodiments, the third self-assembled pattern 62 may be formed from the third DSA formulation by DSA coating and annealing processes such as those described above. The third self-assembled pattern 62 may comprise a plurality of majority blocks 606 and a plurality of minority blocks 608 with corresponding majority critical dimension (CDMa) 610 and minority critical dimension (CDMi) 612 summing to give a third pitch 64, according to embodiments, with CD_{Ma} 610≥CD_{Mi} 612. A third block-size ratio may thus be expressed BR″=(CD_{Ma}/CD_{Mi}). The third block-size ratio may differ from both the first block-size ratio of the base self-assembled pattern and the second (next lower) block-size ratio used to form the first and second steps 132 and 134.

According to various embodiments, the third pitch 64 may be identical to the first pitch 14 and second pitch 18, such that self-alignment of the third self-assembled pattern 62 with the plurality of guides 602 may produce consistent positioning of the majority and minority blocks 606 and 608 with respect to the staircase pattern 19. In other embodiments, the third pitch 64 may approximate the first and second pitches to within a tolerance, as described above.

The third self-assembled pattern 62 may be aligned to the staircase pattern 19 in any manner desirable, according to embodiments. As illustrated in FIG. 6B, the plurality of minority blocks 608 may be aligned to a left edge of the staircase pattern 19. Other embodiments not illustrated may comprise alignment to a right edge or to another position on a second step of a staircase pattern.

With reference now to FIG. 6C, the plurality of majority blocks 606 may be removed by a selective etch process, such as any wet or dry etch that leaves the plurality of minority blocks 608 and the plurality of guides 602 intact and reveals portions of the second neutral layer 614. In embodiments of the selective etch comprising a wet etch, a suitable solvent may be any solvent in which the plurality of majority blocks 606 is soluble and other features are insoluble. In other such embodiments, suitable solvents for the selective etch may be any solvent in which the plurality of majority blocks 606 is soluble and the second neutral layer 604 is only slightly soluble, such that undercutting of the plurality of minority blocks 108 by removal of the portions of the second neutral layer 614 may be minimal or compensated by subsequent planarization, with the other features being insoluble.

The portions of the second neutral layer 614 may then be etched further by another selective etch process, such as any dry etch that leaves the plurality of guides 602 intact, with the plurality of minority blocks 608 serving as mask. This other selective etch may continue until a third step 618 has been formed and an upper surface of the staircase pattern 19 has been revealed flush with remaining portions of the second neutral layer 616, as illustrated in FIG. 6D. A resulting three-step staircase pattern 66 comprises the first step 132, second step 134, and third step 618.

In embodiments not illustrated comprising an etch-stop liner over the staircase pattern 19, etching of the second neutral layer 614 may instead end when the third step 618 has been formed and an upper surface of the etch-stop liner has been revealed flush with remaining portions of the second neutral layer 616. In these embodiments, the three-step staircase pattern may comprise any portions of the etch-stop liner covered by the third step 618.

As illustrated in FIG. 6E, removal of the plurality of minority blocks 608 reveals the three-step staircase pattern 66. According to various embodiments, the plurality of minority blocks 608 may be removed by yet another selective etch process, such as any wet or dry etch that leaves the plurality of guides 602 and the three-step staircase pattern 66 intact. Like the staircase pattern 19 discussed above, the three-step staircase pattern 66 is asymmetric with respect to a mirror axis 142 perpendicular to a direction 140 of the base mandrels 114.

According to various embodiments, the cyclic process may be repeated indefinitely to produce staircase patterns comprising additional steps. In some embodiments, each cycle of the cyclic process may comprise the new step having a new step width smaller than a step width of a next lower step. In some embodiments, this monotonically shrinking step width may be accomplished by selecting a DSA formulation for each new step capable of forming lamellae with a larger block-size ratio than the preceding (next lower) block-size ratio of the preceding (next lower) self-assembled pattern.

FIGS. 7A and 7B illustrate higher staircases that may be produced by additional cycles of the cyclic process, according to various embodiments consistent with the descriptions of FIG. 1A-1H and 6A-6E.

A third cycle of the cyclic process may produce a structure like that illustrated in FIG. 7A, wherein a four-step staircase pattern 72 comprises the steps of the three-step staircase pattern 66 and a fourth step 702, with remaining portions of a third neutral layer 704 surrounding the third step 618.

Similarly, a fourth cycle of the cyclic process may produce a structure like that illustrated in FIG. 7B, wherein a five-step staircase pattern 74 comprises the steps of the four-step staircase pattern 72 and a fifth step 706, with remaining portions of a fourth neutral layer 708 surrounding the fourth step 702.

Like the (two-step) staircase pattern 19 and the three-step staircase pattern 66 discussed above, and according to various embodiments, the four-step staircase pattern 72 and five-step staircase pattern 76 may also be asymmetric with respect to a mirror axis 142 perpendicular to a direction 140 of the base mandrels 114.

As in FIG. 6E, and according to embodiments, etch-stop liners (not illustrated) may be formed to separate each lower staircase pattern in FIGS. 7A and 7B from a surrounding neutral layer and to protect the lower staircase pattern during subsequent etching steps. In such embodiments, the four-and five-step staircase patterns 72 and 74 may comprise respectively any portions of intervening etch-stop liners covered by the fourth step 702 and the fifth step 706.

FIGS. 8A-8E illustrate a method of patterning a substrate by a cyclic process to form a stepped pit. FIG. 8A, in particular, depicts formation of a self-assembled pattern 82 comprising triblock copolymers over an incoming substrate comprising a guide region 80 and a substrate 100 that may be like those described above. The guide region 80 comprises guides 802 and a base neutral layer 804.

According to various embodiments, properties of DSA formulations comprising triblock copolymers (number of blocks k=3) are now described with reference to a general composition ABC or A-b-B-b-C (with C=. . . cccc . . . and an additional “-b-” indicating a second covalent junction between blocks). Differences between triblock and diblock copolymers are emphasized; the discussion of DSA formulations already provided for diblock copolymers may otherwise apply just as well to embodiments comprising triblock copolymers.

Valid triblock copolymer structures with 3 distinct blocks may be written schematically by permuting the blocks ABC. In embodiments in which block C has the same composition as block A, a single unique structure ABA may be obtained, because structure AAB reduces to a diblock copolymer AB. Similarly, in other embodiments in which block C has the same composition as block B, a single unique structure BAB may be obtained.

The assembled configuration of a DSA formulation comprising a generic triblock copolymer depends in the first instance on the volume fractions of blocks A, B, and C (f_{A}, f_{B}, f_{C}∈[0,1] with f_{A}+f_{B}+f_{C}=1); a degree of polymerization N=Nₐ+N_{b}+N_{c}; and 3 Flory-Huggins parameters (χ_{ab}, χ_{ac}, and χ_{bc}) characterizing interactions between pairs of distinct constitutional units. In embodiments comprising triblock copolymers with 2 types of block, such as ABA or BAB, there are still 3 volume fractions and 3 contributions to the degree of polymerization, but there are only 2 Flory-Huggins parameters.

According to various embodiments, and with reference to the generic triblock copolymer ABC, lamellae (lines) may form from triblock copolymers when volume fractions of blocks A and C are comparable, f_{A}≈f_{C}, and when their sum is less than a volume fraction of block B, f_{A}+f_{C}≤f_{B}. For example, in an embodiment, f_{A}=f_{C}=¼ and f_{B}=½. Lamellae may also form, in various other embodiments, when all 3 volume fractions are comparable, f_{A}≈f_{B}≈f_{C}≈⅓. In still other embodiments, Flory-Huggins parameters of the blocks may permit lamellae to form with still other choices of the volume fractions.

Other combinations of volume fractions may produce different assembled configurations comprising various combinations of two-block lamellae; cylinders, in some cases coated coaxially or threaded with rings; spheres, in some cases with a core-shell structure; or gyroid networks. Should the volume fraction of any given block goes to zero, a triblock DSA formulation may reduce to a diblock DSA formulation of the remaining blocks, according to embodiments.

In embodiments comprising a triblock DSA formulation, the base neutral layer 804 may comprise a material that interacts approximately equally favorably with blocks A, B, and C. In some embodiments, the difference between any pair of Flory-Huggins parameters characterizing interactions between the blocks and the neutral layer (χ_{AN}, χ_{BN}, and χ_{CN}) may be less than 0.01.

In some embodiments, the base neutral layer 804 may comprise a random copolymer having the same constitutional units (e.g., a, b, and c) as a triblock copolymer (e.g., ABC) of the DSA formulation. Relative abundances of the constitutional units in the random copolymer may be selected to achieve equal affinity for A, B, and C. In some of these embodiments, these abundances may differ from the volume fractions of the corresponding blocks.

In other embodiments, the base neutral layer 804 may comprise a modified triblock copolymer of the DSA formulation, such as A′-b-B-b-C, A-b-B′-b-C, A-b-B-b-C′, A′-b-B′-b-C, A′-b-B-b-C′, A-b-B′-b-C′, or A′-b-B′-b-C′, where the primed letters indicate chemical modifications to the respective blocks that tune the interactions between them and between unmodified blocks of the DSA formulation to be more balanced.

With further reference to FIG. 8A, the (lamellar) self-assembled pattern 82 may comprise lines formed by blocks having a first polymer composition (A) 806, blocks having a second polymer composition (B) 808, and blocks having a third polymer composition (C) 810. Interactions between the a and c units and a guide material g of the guides (G) 802 may determine whether the self-assembled pattern 82 is structured within the guide region 80 as GABCB . . . ABCBAG or GCBAB . . . CBABCG. The former case may correspond to embodiments in which the guide 802 interacts more favorably with block A of the triblock DSA than with block C (and vice versa for the latter case). As a result, the self-assembled pattern 82 may be self-aligning and symmetric around a midpoint of the guide region 80, with equal numbers, types, and arrangements of lines on either side. In some embodiments, one or both of the guides 802 may comprise an assist layer as described above.

In the illustrated embodiment, the guides 802 interact more favorably with blocks of the first polymer composition 806, such that a repeat unit 85 of the self-assembled pattern 82 may comprise a plurality of blocks ABCB and an end block 86 of the self-assembled pattern 82 may be a block A. In other embodiments, the guides 802 may interact more favorably with the third polymer composition 810, such that a repeat unit of a corresponding self-assembled pattern may instead have a structure CBAB and a corresponding end block may have a structure C.

In both types of embodiments, each block in the plurality of blocks of the repeat unit shares a polymer composition with at most one other block in the plurality of blocks. For example, only a single block in the repeat unit ABCB 85 has polymer composition A 806 or polymer composition C 810. Two blocks in the repeat unit 85 have polymer composition B 808. The end block 86 has a same polymer composition (i.e., as illustrated, polymer composition A 806) as one block in the plurality of blocks of the repeat unit 85.

In various embodiments comprising k-block copolymers with k≥4 and k distinct polymer compositions of the blocks {Pα} with α∈[1, k], a k-block copolymer may have a block structure P₁P2 . . . Pₖ₋₁Pₖ. A corresponding self-assembled pattern may be structured within a guide region to have a repeat unit comprising a plurality of blocks P₁P₂ . . . Pₖ₋₁PₖPₖ₋₁ . . . P₂, according to embodiments forming lamellae. Outer blocks of the copolymer (P₁ and Pₖ) may be associated with blocks of unique polymer composition in the repeat unit. The other blocks of the k-block copolymer (P₂, . . . , Pₖ₋₁) may produce pairs of blocks with the same polymer composition in the repeat unit. This compositional constraint may be understood as a consequence of a mirror symmetry of a corresponding self-assembled pattern.

With further reference then to FIG. 8A, the self-assembled pattern 82 may be symmetric with respect to mirror reflection through a first mirror axis 814 perpendicular to a direction of the repeat units 812.

The self-assembled pattern 82 may comprise a pitch (as indicated by a bracket around the repeat unit 85) corresponding to a width of the repeat unit 85 obtained by summing critical dimensions of the respective blocks. As illustrated, and according to embodiments, the blocks of the repeat unit 85 may have equal or approximately equal critical dimension CD_{block}, such that the pitch may be 4CD_{block}. In corresponding k-block copolymer embodiments, a pitch may be approximately 2(k−1)CD_{block}. In other embodiments, the blocks of the repeat unit 85 may have different critical dimensions.

According to embodiments, the self-assembled pattern 82 may have a pitch (as indicated by a bracket around the repeat unit 85) between 30 nm and 300 nm, for example, between 30 nm and 50 nm, or between 30 nm and 100 nm. The self-assembled pattern 82 may also have a thickness related to the pitch by a multiplicative factor between 1 and 2. In some embodiments, the thickness of the self-assembled pattern 82 may be between 1.2 and 1.7 times its pitch.

Depending on the degree of commensurability of a pitch of the self-assembled pattern 82 with a width of the guide region 80, the self-assembled pattern 82 may still comprise edge features disposed adjacent to the guides 802, such as an edge repeat unit 84, an end block 86 having a different critical dimension from a corresponding in the repeat units 85, or both.

According to various embodiments, a cyclic process may be performed to form a stepped pit that is symmetric with respect to a second mirror axis parallel to the first mirror axis 814. One cycle of the cyclic process may comprise selecting a target composition from the polymer compositions of the plurality of blocks of the repeat unit 85; removing all blocks having that target composition from the self-assembled pattern 82 (i.e., from both the plurality of blocks of the repeat unit 85 and the end block 86, if the first polymer composition 806 of the end block 86 has been selected); and etching the substrate. Formation of a mirror-symmetric stepped pit may determine an order of selection of the target composition in a given cycle, according to embodiments. In various embodiments, a stepped pit having s steps may be produced by performing s cycles of the cyclic process, where positive integer s≥2.

One cycle of the cyclic process is illustrated by FIGS. 8B and 8C. In FIG. 8B, the third polymer composition (C) 810 is selected as the target composition and removed by a selective wet or dry etch like those described above. The etching may form openings 816, pattern fragments 87 comprising portions of neighboring repeat units with structure BAB, and an edge fragment 88 with structure AB. In FIG. 8C, a selective dry etch like those described above forms deeper openings 818 in an etched neutral layer 820.

FIG. 8D depicts the result of a second cycle of the cyclic process. The second polymer composition (B) 808 is selected as the target composition and removed by a selective wet or dry etch, such as those described above. Subsequent selective dry etching may expand the openings 816 to form a stepped pit 822 with two steps in a twice-etched neutral layer 824. The (two-)stepped pit 822 is mirror symmetric with respect to a second mirror axis 826 parallel to the first mirror axis 814. The etching also forms lines 89 and an end block 86E of edge fragment 88 comprising the remaining polymer composition, namely the first polymer composition (A) 806.

A third cycle of the cyclic process may comprise selection of the first polymer composition (A) 806 and removal of the lines 89 and end blocks 86 and 86E by selective wet or dry etching to reveal the (two-)stepped pit 822. In some embodiments, a dry etch such as those described above may form a stepped pit 828 deeper within a thrice-etched neutral layer 830, as depicted in FIG. 8E. In other embodiments, this final etching step may be omitted.

FIGS. 9A-9E illustrate formation of a staircase on a substrate patterned with a stepped pit, according to various embodiments. In particular, these figures illustrate formation of an opening through a step of the stepped pit 828 to form a staircase, such that the staircase may be asymmetric with respect to the second mirror axis 826 parallel to the first mirror axis 814.

According to various embodiments, and with reference to FIG. 9A, the stepped pit 828 may be filled with a filler layer 900. The filler layer 900 may be a neutral layer in the sense described above or comprise another suitable filling material, such as an organic planarizing material. A photoresist layer 902 may then be coated over the substrate 100 and the filler layer 900. According to various embodiments, the photoresist layer 902 may comprise any suitable positive-tone or negative-tone photoresist material.

In FIG. 9B, the photoresist layer 902 is patterned to form an undevelopable region 904 and a developable region 906. The developable region 906 may be aligned to a first step 907 of the stepped pit 828. In some embodiments, alignment of the developable region 906 may be performed using a global alignment marker, such as a wafer notch.

According to various embodiments, and as illustrated, the first step 907 may be a left first step of the stepped pit 828. In other embodiments, the first step 907 may be a right first step of the stepped pit 828 obtained by reflection through the second mirror axis 826. The respective embodiments may vary by a direction of a resulting staircase, i.e., whether the resulting staircase will ascend from left to right or vice versa.

With reference now to FIG. 9C, the developable region 906 is developed using an appropriate photoresist developer to form openings 908 that reveal portions of the filler layer 900. In FIG. 9D, these portions of the filler layer 900 are etched by a selective dry etch such as those described above, forming deeper openings 910 in an etched filler layer 912 and revealing the first step 907. Finally, as illustrated in FIG. 9E, the first step is etched by a selective dry etch such as those described above to form a staircase 916.

According to various embodiments, for a stepped pit comprising s steps, the staircase 916 may comprise s+1 steps. For example, the (two-)stepped pit 828 may be used to form the (three-step) staircase 916. The staircase 916 (and a staircase pattern 90 comprising the staircase 916 and left and right edge features 918 and 920 that are disposed adjacent to the guides 802) is asymmetric with respect to the second mirror axis 826 and also with respect to the first mirror axis 814, along similar lines as described above with reference to FIGS. 2A and 2B.

In a stepped pit comprising s steps, step 0 may be a bottom of the pit, and step s may be a top of the pit. Thus, there may be s+1 step-aligned patterning and etching processes like those just described with reference to FIG. 9A-9E. Etching step 0 or step s may produce spaced symmetric structures, namely, separated stepped towers or separated stepped pits comprising s−1 steps, according to the respective embodiments. Etching any intermediate step other than step 1 (e.g., the first step 907) may produce asymmetric nonmonotonic staircases, in various embodiments.

In various embodiments not illustrated here, the edge features 918 and 920 may be left in place, and the photoresist layer 902, the etched filler layer 912, or the guides 802 may be removed individually or in combination. The choice of subsequent processing steps may depend on whether the staircase pattern is to be used directly or transferred to underlying layers of the substrate 100.

In some embodiments, the edge features 918 and 920 may be removed using spacer methods, such as those described above with reference to FIGS. 4A-4D. In other embodiments, further patterning of the undevelopable regions 904 (i.e., patternable photoresist material) over the left and right edge features 918 and 920 in FIG. 9E may be used. FIGS. 10A-10D illustrate cross-sectional views of different stages of one such method of removing edge features from a substrate comprising a staircase pattern formed by (e.g.) the method of FIGS. 9A-9E, according to various embodiments.

Referring to FIG. 10A, the photoresist layer 902 is patterned further to form developable regions 1000 and undevelopable regions 1002, with the developable regions 1000 being aligned to left and right edge features 918 and 920 that are each adjacent to a respective staircase 916. In other words, the patterning may be aligned to a width or widths around guides 802.

In FIG. 10B, the developable regions 1000 are developed to form edge openings 1004 and expose the edge features 918 and 920. In FIG. 10C, the edge features 918 and 920 are removed by a selective dry etch to form cleaned edges 1006. The remaining portions of the staircase pattern 90 form a trimmed staircase pattern 1008. In FIG. 10D, the undevelopable region 1002 of the photoresist layer 902 is stripped to reveal the trimmed staircase pattern 1008. In some embodiments (not illustrated), stripping of the photoresist layer 902 may further strip the etched filler layer 912.

According to various embodiments, additional processing steps may follow edge feature removal. In some embodiments, the etched filler layer 912 may be stripped and the guides 802 may be removed, depending on the intended purpose of the trimmed staircase pattern 1008.

FIG. 11 illustrates structures comprising various constitutional units that may be part of polymer materials making up self-assembled patterns, guides, neutral layers, or block copolymers described herein. In each structure depicted, a bracketed portion of the structure is a constitutional unit comprising a backbone (fully enclosed within the brackets) and a sidechain (falling outside of the brackets). The constitutional unit (e.g., symbolically, constitutional unit a) may be repeated n times, with n being any positive integer. Asterisks (*) on either side of the brackets may separately indicate a neighboring constitutional unit of a different composition (b, c, etc.) in a copolymer, such as an alternating (e.g., . . . abababab . . . ), periodic (e.g., . . . aabaabaabaab . . . or . . . abcabcabcabc . . . ), or random copolymer; a neighboring constitutional unit of the same type or a neighboring block in a block copolymer (e.g., . . . aaaa-bbbb . . . ); or an end group whose detailed structure may be determined by the manner in which a given embodiment polymer is synthesized. When both asterisks indicate end groups, the corresponding structure may thus be a homopolymer (e.g., . . . aaaa . . . ).

With further reference to FIG. 11 as a whole, stereochemistry is not indicated exhaustively. All possible stereoisomers, diastereomers (including meso configurations), and cis or trans conformations of double bonds consistent with a given constitutional unit may be used, according to various embodiments of the present disclosure. Similarly, any and all tacticities of the corresponding polymers or blocks may be used in various embodiments, including isotactic (uniform stereochemistry), syndiotactic (alternating stereochemistry), eutactic (stereochemistry repeating in a predictable but more complex fashion), or atactic (random stereochemistry).

Referring now to particular structures illustrated in FIG. 11, various embodiment polymers may comprise polystyrene (PS) 1100, poly(4-hydroxystyrene) (PHS) 1101, or poly(2-vinylpyridine) (P2VP) 1102.

Various embodiment polymers may comprise poly(vinyl acetate) PVA) 1104. In some embodiments, polymers comprising PVA 1104 may further comprise poly(vinyl alcohol) 1106, which may be present as an incidental hydrolysis product of PVA 1104, an intentional chemical modification thereof, or both.

Various embodiment polymers may comprise poly(ethylene oxide) (PEO) 1108, also referred to as polyethylene glycol (PEG), or poly(propylene oxide) (PPO) 1109, also referred to as polypropylene glycol (PPG).

Various embodiment polymers may comprise poly(vinylidene fluoride) (PVDF) 1110, or polyhexafluoropropylene (PHFP) 1111, or a perfluorinated polymer related to PPO 1109, perfluorpolyether-K (PFPE-K) 1113. Embodiments may include blocks comprising a random copolymers of vinylidene fluoride (VDF) and hexafluoropropylene (HFP) constitutional units, poly(VDF-co-HFP). Other perfluoropolyethers such as PFPE-A, PFPE-D, PFPE-Y, and PFPE-Z may also be part of various embodiment polymers.

Various embodiment polymers may comprise polydimethylsiloxane (PDMS) 1112 or another suitable silicone.

Various embodiment polymers may comprise polybutadiene (PB), more properly referred to as poly(1,3-butadiene). Embodiments comprising polybutadiene may comprise any mixture of poly(cis-) and poly(trans-butadiene) (represented in FIG. 11 by poly(cis-butadiene) 1114CT) and poly(vinyl-butadiene) 1114V

Various embodiment polymers may comprise polyisoprene (PI). Embodiments comprising polyisoprene may comprise any mixture of poly(cis-) and poly(trans-isoprene) (represented in FIG. 11 by poly(cis-isoprene) 1116CT), poly(3,4-vinyl-isoprene) 1116Va, and poly(1,2-vinyl-isoprene) 1116Vb.

Various embodiment polymers may comprise polyethylenepropylene (PEP) 1118, also referred to as poly(ethylene-co-propylene) or poly(methyl butylene). In some embodiments, PEP 1118 may be obtained by hydrogenation of poly(cis-) or poly(trans-isoprene) 1116CT.

Various embodiment polymers may comprise a poly(hydrocarbacrylate) 1120 or a poly(hydrocarbacrylic acid) 1122, with pendant groups R¹ and R² being separately selected from a hydrogen atom or a hydrocarbyl group (an organic group comprising carbon atoms and hydrogen atoms, with a single open valence at one of the carbon atoms). A poly(hydrocarbacrylic acid) 1122 may correspond to a poly(hydrocarbacrylate) 1120 with R²selected to be a hydrogen atom. Selecting R¹ of a poly(hydrocarbacrylic acid) 1122 to be a hydrogen atom yields poly(acrylic acid) (PAA) 1124, which may be part of various embodiment polymers.

Selecting R¹ of a poly(hydrocarbacrylate) 1120 to be a hydrogen atom may yield a poly(hydrocarbyl acrylate), in various embodiments. Further selecting R² to be an alkyl group may yield a poly(alkyl acrylate) such as poly(methyl acrylate) (PMA, not illustrated) or poly(n-butyl acrylate) (PBA), in various embodiments.

Various embodiment polymers may comprise a poly(methacrylate) obtained by selecting R² of a poly(hydrocarbacrylate) 1120 to be a methyl group (—Me═—CH₃). Selecting R¹ to be a hydrogen atom or an alkyl group may yield poly(methacrylic acid) (PMA), poly(methyl methacrylate) (PMMA) 1126, poly(ethyl methacrylate), etc., according to various embodiments.

Various embodiment polymers may comprise poly(N,N-dimethylacrylamide) (PDMA) 1130, poly(lactic acid) (PLA) 1132, or polyisobutylene (PIB) 1134.

Structures illustrated in FIG. 11 correspond to polymers with a variety of backbone chemistries, including alkanes (1100-1106, 1114V, 1116Va/b, 1118-1130, 1134) and fluoroalkanes (1110, 1111); alkenes (1114CT, 1116CT); ethers (1108, 1109) and fluoroethers (1113), siloxanes (1112), and esters (1132). Other examples of backbone chemistries belonging to these classes but not presented here may be selected for use in various embodiments. In embodiments comprising fluorinated backbone chemistries, the fluorination may replace one hydrogen, multiple hydrogens (polyfluorination), or every hydrogen (perfluorination) in the backbone.

Other backbone chemistries that may be selected consistent with embodiments of the present disclosure comprise other haloalkanes (including poly-and perhaloalkanes), other haloethers (including poly-and perhaloethers), amides, imides, oxalates, carbonates, metal oxides, metal-organics, combinations thereof or with the illustrated backbone chemistries, and the like. In some embodiments, combinations of different backbone chemistries may reflect formation of a polymer by condensation of two or more multifunctional precursors.

Structures illustrated in FIG. 11 correspond to polymers with a variety of sidechain functionalities as well, including phenyl groups (1100), 4-hydroxyphenyl or phenolic groups (1101), pyridinyl groups (1102), esters linked to the backbone through the ester oxygen (1104) or the ester carbonyl (1120, 1126, 1128), alcohols (1106), alkyls (1109, 1112, 1116CT, 1116Vb, 1118, 1126, 1130, 1134), fluoroalkyls (1111, 1113), vinyls (1114V, 1116Va/b), hydrocarbyls (1120, 1122), carboxylic acids (1122, 1124), and amides (1132). Other examples of sidechains belonging to these classes but not presented here, such as sidechains combining these functionalities, may be selected for use in various embodiments. (For example, some embodiments may comprise poly(hydroxyethyl methacrylate) (PHEMA).) In embodiments comprising fluorinated sidechains, the fluorination may replace one hydrogen, multiple hydrogens (polyfluorination), or every hydrogen (perfluorination) in the backbone.

Other sidechain functionalities that may be selected consistent with embodiments of the present disclosure comprise other haloalkyls (including poly-and perhaloalkyls), other aryls (phenyl derivatives), other pyridinyl derivatives, adamantyls, silanes, amines, ferrocenyls ((—C₅H₄)Fe(C₅H₅)) and other organometallic sandwich compounds with a hydrogen atom having been removed to form an open valence, combinations thereof or with the illustrated sidechain functionalities, and the like.

Constitutional units comprising combinations of any of the aforementioned types of backbone chemistries and any of the aforementioned types of sidechains may be used in various embodiments of the present disclosure. In some embodiments comprising ionizable functionalities like carboxylic acids (1122, 1124), materials used may comprise counterions that yield an overall neutral charge.

In some embodiments, polymer composites may be used that comprise one or more polymers together with another type of material, such as metal or metalloid nanoparticles coated with aliphatic groups (non-aromatic hydrocarbons). Some embodiments may comprise gold nanoparticles coated with organic groups by coupling to a linear or branched thioalkyl (—SCₘH₂ₘ₊₁) with integer m between 1 and 20. Some embodiments may comprise silica nanoparticles coated by coupling to a disilazane (R₃Si(NH)SiR₃), wherein the R groups comprise linear or branched alkyl groups (—CₘH₂ₘ₊₁) with integer m between 1 and 20.

Example diblock copolymers that may be used in embodiments illustrated by FIGS. 1-7 comprise PS-b-PB, PS-b-PBA, PS-b-PMMA (several aspects of which are described above), PS-b-PAA, PS-b-PVDF, PIB-b-PMMA, or (PFPE-K)-b-poly(VDF-co-HFP).

Other embodiment diblock copolymers may include PS-b-P2VP, which may be synthesized with ultrahigh molecular weight (and thus high degree of polymerization) in order to produce a pitch of approximately 100 nm. An embodiment diblock copolymer composite may comprise PS-b-PEP blended with thioalkyl-coated gold nanoparticles with m=18 and with silica nanoparticles coated by coupling to hexamethylenedisilazane (R₃Si(NH)SiR₃ with —R=—Me═—CH₃), which may also provide periods near or above 100 nm.

In some embodiments, a DSA formulation suitable for process flows illustrated in FIGS. 1-7 may comprise an ABA-type triblock copolymer rather than a diblock copolymer. Such symmetric triblock copolymers may form lamellae of alternating A and B compositions but may behave differently from corresponding AB diblock copolymers owing to the middle block being tethered at each end. This double-tethering may provide advantages such as enhanced phase separation between blocks, improved pattern fidelity, modified defect behavior during self-assembly, and the like.

Example symmetric triblock copolymers that may be used in embodiments illustrated in FIGS. 1-7 comprise PS-b-PB-b-PS and PS-b-PDMS-b-PS. Another class of examples that may be used in some embodiments is pluronic triblock copolymers (poloxamers) comprising various degrees of polymerization of PEO-b-PPO-b-PEO.

Examples of triblock copolymers that may be used in embodiments illustrated by FIGS. 8-10 comprise PS-b-PI-b-P2VP, PS-b-P2VP-b-PEO, PS-b-PDMA-b-PLA, PS-b-PMMA-b-PEO, PI-b-PS-b-P2VP, PDMS-b-PEO-b-PPO, and PI-b-PS-b-PEO.

The process flows described with reference to FIGS. 1A-1H may represent various embodiments of a more general method of patterning a substrate, as illustrated by a flow chart in FIGS. 12A and 12B.

In block 1201 of FIG. 12A, a guide pattern comprising a plurality of guides and a plurality of first neutral regions is formed over the substrate, resulting (according to some embodiments) in a structure like that in FIG. 1A. In some embodiments, the guides may comprise an assist layer configured to be wetted by a first composition or a second composition of a first self-assembled pattern to be formed subsequently, as illustrated in FIG. 3.

Next, in block 1202, the first self-assembled pattern is formed over the plurality of first neutral regions, resulting (according to some embodiments) in a structure like that in FIG. 1B. The first self-assembled pattern comprises a first plurality of blocks having the first composition, a second plurality of blocks having the second composition, and a first block-size ratio between a first critical dimension of one of the first plurality of blocks and a second critical dimension of one of the second plurality of blocks. Then, in block 1203, the first self-assembled pattern is transferred to the plurality of neutral regions to form a plurality of first neutral mandrels and a plurality of openings, resulting (according to some embodiments) in a structure like that in FIG. 1C.

Continuing with block 1204 of FIG. 12A, the substrate is coated with a second neutral layer to cover the plurality of first neutral mandrels and fill the plurality of openings, resulting (according to some embodiments) in a structure like that in FIG. 1D. In some embodiments comprising guides with an assist layer, though not as illustrated, the assist layer may then be modified to be wetted by a third composition or a fourth composition of a second self-assembled pattern to be formed subsequently, as illustrated in FIG. 3.

Following connector 1205 of FIG. 12A to connector 1206 of FIG. 12B and then to block 1207, a second self-assembled pattern is formed over the second neutral layer, resulting (according to some embodiments) in a structure like that in FIG. 1E. The second self-assembled pattern comprises a third plurality of blocks having a third composition, a fourth plurality of blocks having a fourth composition, and a second block-size ratio between a third critical dimension of one of the third plurality of blocks and a fourth critical dimension of one of the fourth plurality of blocks. The second block-size ratio is different from the first block-size ratio.

Continuing with block 1208 of FIG. 12B, the third plurality of blocks is etched to reveal portions of the second neutral layer, resulting (according to some embodiments) in a structure like that in FIG. 1F. Next, in block 1209, the portions of the second neutral layer are etched to reveal the plurality of first neutral mandrels and form a staircase pattern, resulting (according to some embodiments) in a structure like that in FIG. 1G. Then, in block 1210, the fourth plurality of blocks is etched, yielding (according to some embodiments) an outgoing substrate like that in FIG. 1H. In some embodiments, edge removal (as in FIGS. 4A-4D), guide removal (as in FIGS. 5A and 5B), or both may then be performed.

The process flows described with reference to FIGS. 1A-1H, FIGS. 6A-6E, and FIGS. 7A and 7B may represent various embodiments of a more general method of patterning a substrate, as illustrated by a flow chart in FIG. 13.

In block 1301, a plurality of base mandrels is formed over the substrate from a base self-assembled pattern comprising a base block-size ratio. In various embodiments, the plurality of base mandrels may be formed by process flows such as those depicted in FIGS. 1A-1C. Next, in block 1302, a cyclic process is performed to form a staircase pattern comprising steps. Each cycle of the cyclic process comprises (per sub-block 1321) forming a new step of the staircase pattern using directed self-assembly.

According to various embodiments, a first step and a second step of the staircase pattern may be formed by process flows such as that depicted in FIGS. 1D-1H; a third step of the staircase pattern may be formed by process flows such as that depicted in FIGS. 6A-6E; and a fourth step, a fifth step, and any higher step of the staircase pattern may be formed by similar processes to those depicted in FIGS. 1D-1H or FIGS. 6A-6E. In some embodiments, a staircase pattern comprising a fourth step may be similar to that depicted in FIG. 7A, and a staircase pattern comprising a fifth step may be similar to that depicted in FIG. 7B.

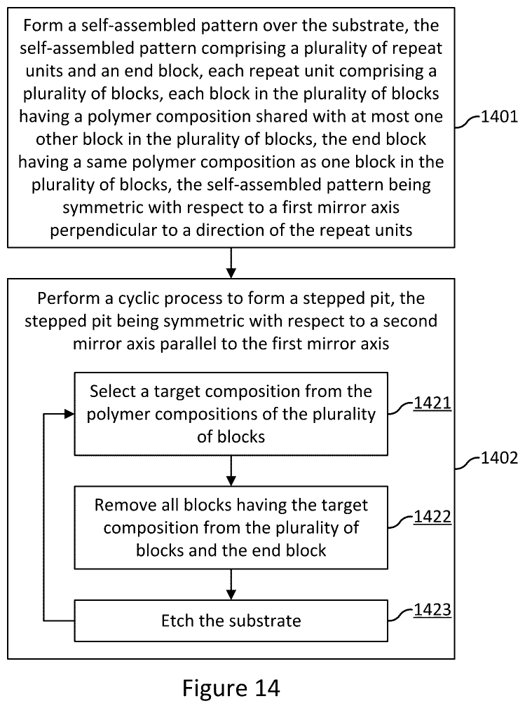

The process flows described with reference to FIGS. 8A-8E may represent various embodiments of a more general method of patterning a substrate, as illustrated by a flow chart in FIG. 14.

In block 1401, a self-assembled pattern is formed over the substrate. The self-assembled pattern comprises a plurality of repeat units (each repeat unit comprising a plurality of blocks) and an end block. Each block in the plurality of blocks has a polymer composition shared with at most one other block in the plurality of blocks, and the end block has a same polymer composition as one block in the plurality of blocks. The self-assembled pattern is symmetric with respect to a first mirror axis perpendicular to a direction of the repeat units. According to various embodiments, forming the self-assembled pattern over the substrate may result in a structure like that depicted in FIG. 8A.

Next, in block 1402, a cyclic process is performed to form a stepped pit, the stepped pit being symmetric with respect to a second mirror axis parallel to the first mirror axis. One cycle of the cyclic process comprises the following: In sub-block 1421, a target composition is selected from the polymer compositions of the plurality of blocks. Next, in sub-block 1422, all blocks having the target composition are removed from the plurality of blocks and from the end block. Then, in sub-block 1423, the substrate is etched.

According to various embodiments, sub-blocks 1421 and 1422 together may produce a structure like that in FIG. 8B from structures like that depicted in FIG. 8A. Sub-block 1423 may then result in a structure like that in FIG. 8C. An additional cycle may produce a structure like that in FIG. 8D, and yet another cycle may produce a structure like that in FIG. 8E. Stepped pits comprising more than two steps may be formed in embodiments comprising four or more polymer compositions by continuing to repeat the cyclic process of block 1402.

In some embodiments, edge removal (as in FIGS. 10A-10D, or using a spacer method similar to that in FIGS. 4A-4D), guide removal (not illustrated), or both may then be performed.

Example embodiments of the invention are described below. Other embodiments can also be understood from the entirety of the specification as well as the claims filed herein.

Example 1. A method of patterning a substrate includes forming a plurality of base mandrels over the substrate from a base self-assembled pattern and performing a cyclic process to form a staircase pattern including steps. Each cycle of the cyclic process includes forming a new step of the staircase pattern using directed self-assembly. The base self-assembled pattern includes a base block-size ratio.

Example 2. The method of example 1, where the staircase pattern is asymmetric with respect to a mirror axis perpendicular to a direction of the base mandrels.

Example 3. The method of one of examples 1 or 2, where each cycle of the cyclic process includes the new step having a new step width smaller than a step width of a next lower step.

Example 4. The method of one of examples 1 to 3, where forming a new step of the staircase pattern using directed self-assembly includes forming a neutral layer over the substrate; forming another self-assembled pattern over the neutral layer, the another self-assembled pattern including a plurality of majority blocks including a majority critical dimension, a plurality of minority blocks including a minority critical dimension, and a block-size ratio between the majority critical dimension and the minority critical dimension different from a next lower block-size ratio of a next lower self-assembled pattern; etching the plurality of majority blocks to reveal portions of the neutral layer; etching the portions of the neutral layer to form the new step of the staircase pattern; and etching the plurality of minority blocks.

Example 5. The method of example 4, where each plurality of majority blocks includes polystyrene.

Example 6. The method of one of examples 4 or 5, where each plurality of minority blocks includes polybutadiene, polyisoprene, polyethylenepropylene, a poly(hydrocarbacrylic acid), a poly(hydrocarbacrylate), poly(ethylene oxide), poly(propylene oxide), poly(vinyl acetate), poly(vinylidene fluoride), polyhexafluoropropylene, perfluoropolyether-K, poly(2-vinylpyridine), polyisobutylene, or polydimethylsiloxane.

Example 7. The method of one of examples 1 to 6, where forming the plurality of base mandrels from the base self-assembled pattern includes forming a guide pattern over the substrate, the guide pattern including a plurality of guides and a base neutral layer; forming the base self-assembled pattern over the base neutral layer; and transferring the base self-assembled pattern to the base neutral layer.

Example 8. A method of patterning a substrate includes forming a self-assembled pattern over the substrate, the self-assembled pattern including a plurality of repeat units and an end block, each repeat unit including a plurality of blocks, each block in the plurality of blocks having a polymer composition shared with at most one other block in the plurality of blocks, the end block having a same polymer composition as one block in the plurality of blocks, the self-assembled pattern being symmetric with respect to a first mirror axis perpendicular to a direction of the repeat units; and performing a cyclic process to form a stepped pit, the stepped pit being symmetric with respect to a second mirror axis parallel to the first mirror axis. One cycle of the cyclic process includes selecting a target composition from the polymer compositions of the plurality of blocks; removing all blocks having the target composition from the plurality of blocks and the end block; and etching the substrate.

Example 9. The method of example 8, further including forming an opening through a step of the stepped pit to form a staircase, the staircase being asymmetric with respect to the second mirror axis.

Example 10. The method of example 9, where an edge feature is disposed adjacent to the staircase, the method further including forming a photoresist layer over the substrate; patterning the photoresist layer to form a developable region and an undevelopable region, the developable region being aligned to the edge feature; removing the developable region of the photoresist layer to reveal the edge feature; and removing the edge feature.

Example 11. The method of example 8, where the stepped pit includes a first step, the method further including filling the stepped pit with a neutral layer; coating the substrate and the neutral layer with a photoresist layer; patterning the photoresist layer to form a developable region and an undevelopable region, the developable region being aligned to the first step; removing the developable region of the photoresist layer to reveal a portion of the neutral layer; etching the portion of the neutral layer to reveal the first step; and etching the first step to form a staircase, the staircase being asymmetric with respect to the second mirror axis.

Example 12. The method of one of examples 8 to 11, where the polymer compositions of the blocks in each plurality of blocks and of the end block include polystyrene, polybutadiene, polyisoprene, poly(ethylene oxide), poly(propylene oxide), poly(2-vinyl pyridine), polydimethylsiloxane, poly(N,N-dimethylacrylamide), or poly(lactic acid).

Example 13. A method of patterning a substrate includes forming a first self-assembled pattern over a plurality of first neutral regions, the first self-assembled pattern including a first plurality of blocks having a first composition, a second plurality of blocks having a second composition, and a first block-size ratio between a first critical dimension of one of the first plurality of blocks and a second critical dimension of one of the second plurality of blocks; transferring the first self-assembled pattern to the plurality of first neutral regions to form a plurality of first neutral mandrels and a plurality of openings; coating the substrate with a neutral layer to cover the plurality of first neutral mandrels and fill the plurality of openings; forming a second self-assembled pattern over the neutral layer, the second self-assembled pattern including a third plurality of blocks having a third composition, a fourth plurality of blocks having a fourth composition, and a second block-size ratio between a third critical dimension of one of the third plurality of blocks and a fourth critical dimension of one of the fourth plurality of blocks, the second block-size ratio being different from the first block-size ratio; etching the third plurality of blocks to reveal portions of the neutral layer; etching the portions of the neutral layer to reveal the plurality of first neutral mandrels and form a staircase pattern; and etching the fourth plurality of blocks.

Example 14. The method of example 13, where the staircase pattern is asymmetric with respect to a mirror axis perpendicular to a direction of the first neutral mandrels.

Example 15. The method of one of examples 13 or 14, further including forming a guide pattern over the substrate, the guide pattern including a plurality of guides and the plurality of first neutral regions, where the plurality of guides include an assist layer configured to be wetted by the first composition or the second composition.

Example 16. The method of example 15, where wetting of the assist layer increases a pattern density of the staircase pattern.

Example 17. The method of one of examples 15 or 16, further including, before forming the second self-assembled pattern over the neutral layer, modifying the assist layer to be wetted by the third composition or the fourth composition.

Example 18. The method of one of examples 13 to 17, where the staircase pattern includes edge features disposed adjacent to a plurality of guides, the method further including depositing a plurality of spacers aligned with the edge features around the plurality of guides; coating a protective layer over the staircase pattern; etching the plurality of spacers; and removing the edge features.

Example 19. The method of one of examples 13 to 18, further including removing the plurality of guides; and etching the plurality of first neutral mandrels.

Example 20. The method of one of examples 13 to 19, where the first composition includes polystyrene.

Example 21. The method of one of examples 13 to 20, where the second composition includes polybutadiene, polyisoprene, polyethylenepropylene, a poly(hydrocarbacrylic acid), a poly(hydrocarbacrylate), poly(ethylene oxide), poly(propylene oxide), poly(vinyl acetate), poly(vinylidene fluoride), polyhexafluoropropylene, perfluoropolyether-K, poly(2-vinylpyridine), polyisobutylene, or polydimethylsiloxane.

Example 22. The method of one of examples 13 to 21, where the first composition and the third composition are a first same composition, where the second composition and the fourth composition are a second same composition.

Example 23. The method of one of examples 13 to 22, where a width of a staircase of the staircase pattern is between 30 nm and 300 nm.

While this invention has been described with reference to illustrative embodiments, this description is not intended to be construed in a limiting sense. Various modifications and combinations of the illustrative embodiments, e.g., of FIGS. 1-14, as well as other embodiments of the invention, will be apparent to persons skilled in the art upon reference to the description. It is therefore intended that the appended claims encompass any such modifications or embodiments.

What is claimed is:

1. A method of patterning a substrate, the method comprising:
forming a plurality of base mandrels over the substrate from a base self-assembled pattern comprising a base block-size ratio; and
performing a cyclic process to form a staircase pattern comprising steps, each cycle of the cyclic process comprising:
forming a new step of the staircase pattern using directed self-assembly.

2. The method of claim 1, wherein the staircase pattern is asymmetric with respect to a mirror axis perpendicular to a direction of the base mandrels.

3. The method of claim 1, wherein each cycle of the cyclic process comprises the new step having a new step width smaller than a step width of a next lower step.

4. The method of claim 1, wherein forming a new step of the staircase pattern using directed self-assembly comprises:
forming a neutral layer over the substrate;
forming another self-assembled pattern over the neutral layer, the another self-assembled pattern comprising a plurality of majority blocks comprising a majority critical dimension, a plurality of minority blocks comprising a minority critical dimension, and a block-size ratio between the majority critical dimension and the minority critical dimension different from a next lower block-size ratio of a next lower self-assembled pattern;
etching the plurality of majority blocks to reveal portions of the neutral layer;
etching the portions of the neutral layer to form the new step of the staircase pattern; and
etching the plurality of minority blocks.

5. The method of claim 4, wherein each plurality of majority blocks comprises polystyrene.

6. The method of claim 4, wherein each plurality of minority blocks comprises polybutadiene, polyisoprene, polyethylenepropylene, a poly(hydrocarbacrylic acid), a poly(hydrocarbacrylate), poly(ethylene oxide), poly(propylene oxide), poly(vinyl acetate), poly(vinylidene fluoride), polyhexafluoropropylene, perfluoropolyether-K, poly(2-vinylpyridine), polyisobutylene, or polydimethylsiloxane.

7. A method of patterning a substrate, the method comprising:
forming a self-assembled pattern over the substrate, the self-assembled pattern comprising a plurality of repeat units and an end block, each repeat unit comprising a plurality of blocks, each block in the plurality of blocks having a polymer composition shared with at most one other block in the plurality of blocks, the end block having a same polymer composition as one block in the plurality of blocks, the self-assembled pattern being symmetric with respect to a first mirror axis perpendicular to a direction of the repeat units; and
performing a cyclic process to form a stepped pit, the stepped pit being symmetric with respect to a second mirror axis parallel to the first mirror axis, one cycle of the cyclic process comprising:
selecting a target composition from the polymer compositions of the plurality of blocks;
removing all blocks having the target composition from the plurality of blocks and the end block; and
etching the substrate.

8. The method of claim 7, further comprising:
forming an opening through a step of the stepped pit to form a staircase, the staircase being asymmetric with respect to the second mirror axis.

9. The method of claim 8, wherein an edge feature is disposed adjacent to the staircase, the method further comprising:
forming a photoresist layer over the substrate;
patterning the photoresist layer to form a developable region and an undevelopable region, the developable region being aligned to the edge feature;
removing the developable region of the photoresist layer to reveal the edge feature; and
removing the edge feature.

10. The method of claim 7, wherein the stepped pit comprises a first step, the method further comprising:
filling the stepped pit with a neutral layer;
coating the substrate and the neutral layer with a photoresist layer;
patterning the photoresist layer to form a developable region and an undevelopable region, the developable region being aligned to the first step;
removing the developable region of the photoresist layer to reveal a portion of the neutral layer;
etching the portion of the neutral layer to reveal the first step; and
etching the first step to form a staircase, the staircase being asymmetric with respect to the second mirror axis.

11. The method of claim 7, wherein the polymer compositions of the blocks in each plurality of blocks and of the end block comprise polystyrene, polybutadiene, polyisoprene, poly(ethylene oxide), poly(propylene oxide), poly(2-vinyl pyridine), polydimethylsiloxane, poly(N,N-dimethylacrylamide), or poly(lactic acid).

12. A method of patterning a substrate, the method comprising:
forming a first self-assembled pattern over a plurality of first neutral regions, the first self-assembled pattern comprising a first plurality of blocks having a first composition, a second plurality of blocks having a second composition, and a first block-size ratio between a first critical dimension of one of the first plurality of blocks and a second critical dimension of one of the second plurality of blocks;
transferring the first self-assembled pattern to the plurality of first neutral regions to form a plurality of first neutral mandrels and a plurality of openings;
coating the substrate with a neutral layer to cover the plurality of first neutral mandrels and fill the plurality of openings;
forming a second self-assembled pattern over the neutral layer, the second self-assembled pattern comprising a third plurality of blocks having a third composition, a fourth plurality of blocks having a fourth composition, and a second block-size ratio between a third critical dimension of one of the third plurality of blocks and a fourth critical dimension of one of the fourth plurality of blocks, the second block-size ratio being different from the first block-size ratio;
etching the third plurality of blocks to reveal portions of the neutral layer;
etching the portions of the neutral layer to reveal the plurality of first neutral mandrels and form a staircase pattern; and
etching the fourth plurality of blocks.

13. The method of claim 12, wherein the staircase pattern is asymmetric with respect to a mirror axis perpendicular to a direction of the first neutral mandrels.

14. The method of claim 12, further comprising forming a guide pattern over the substrate, the guide pattern comprising a plurality of guides and the plurality of first neutral regions, wherein the plurality of guides comprise an assist layer configured to be wetted by the first composition or the second composition.

15. The method of claim 14, wherein wetting of the assist layer increases a pattern density of the staircase pattern.

16. The method of claim 14, further comprising:
before forming the second self-assembled pattern over the neutral layer, modifying the assist layer to be wetted by the third composition or the fourth composition.

17. The method of claim 12, wherein the staircase pattern comprises edge features disposed adjacent to a plurality of guides, the method further comprising:
depositing a plurality of spacers aligned with the edge features around the plurality of guides;
coating a protective layer over the staircase pattern;
etching the plurality of spacers; and
removing the edge features.

18. The method of claim 12, wherein the first composition comprises polystyrene.

19. The method of claim 18, wherein the second composition comprises polybutadiene, polyisoprene, polyethylenepropylene, a poly(hydrocarbacrylic acid), a poly(hydrocarbacrylate), poly(ethylene oxide), poly(propylene oxide), poly(vinyl acetate), poly(vinylidene fluoride), polyhexafluoropropylene, perfluoropolyether-K, poly(2-vinylpyridine), polyisobutylene, or polydimethylsiloxane.

20. The method of claim 12, wherein a width of a staircase of the staircase pattern is between 30 nm and 300 nm.
